(19) United States
(12) Patent Application Publication
(10) Pub. No.: US 2026/0336641 A1
(43) Pub. Date: Oct. 29, 2026

(54) COOLING SYSTEM, COOLING EXECUTION DEVICE, COOLING DEVICE, COOLING EXECUTION METHOD, COOLING METHOD, PROGRAM, COOLING EXECUTION PROGRAM, AND COOLING PROGRAM

(71) Applicant: SoftBank Group Corp., Tokyo (JP)

(72) Inventor: Masayoshi SON, Tokyo (JP)

(21) Appl. No.: 19/117,866

(22) PCT Filed: Oct. 3, 2023
(86) PCT No.: PCT/JP2023/036112

§ 371 Date: Apr. 2, 2025

(30) Foreign Application Priority Data
Oct. 4, 2022 (JP) 2022-160556
Oct. 20, 2022 (JP) 2022-168655
Jan. 4, 2023 (JP) 2023-000212
Jan. 4, 2023 (JP) 2023-000289
Jan. 5, 2023 (JP) 2023-000430
Jan. 5, 2023 (JP) 2023-000632
Jan. 12, 2023 (JP) 2023-003401
Jan. 13, 2023 (JP) 2023-003782
Jan. 13, 2023 (JP) 2023-003817
Jan. 18, 2023 (JP) 2023-006003

(51) Int. Cl. B60W 50/02; B60W 50/00; B60W 60/00; G05D 1/69; G05D 23/00; G05D 109/10; H05K 7/20

(52) U.S. Cl. CPC B60W 50/0225; B60W 50/0097; B60W 60/001; G05D 1/69; G05D 23/00; H05K 7/20845; B60W 2420/403; B60W 2556/65; G05D 2109/10

(57) ABSTRACT

Provided is a cooling execution device including: a prediction unit that predicts a temperature change of a control device that controls automatic driving of a vehicle and that is mounted on the vehicle; and a cooling execution unit that starts cooling the control device based on the temperature change predicted by the prediction unit. Provided is a cooling execution method to be executed by a computer, including: a prediction stage of predicting a temperature change of a control device that controls automatic driving of a vehicle and that is mounted on the vehicle; and a cooling execution stage of starting cooling the control device based on the temperature change predicted in the prediction stage.

### FIELD

The present invention relates to a cooling system, a cooling execution device, a cooling device, a cooling execution method, a cooling method, a program, a cooling execution program, and a cooling program.

### BACKGROUND

Patent Literature 1 describes a vehicle having an automatic driving function.

### CITATION LIST

### Patent Literature Patent Literature 1: JP 2022-035198 A

### SUMMARY

### Technical Problem

It is desired to achieve a cooling system, a cooling execution device, a cooling device, a cooling execution method, a cooling method, a program, a cooling execution program, and a cooling program, which perform efficient cooling in accordance with a temperature change of a control device of a vehicle.

### Solution to Problem

An aspect of an embodiment provides a cooling execution device. The cooling execution device includes a prediction unit that predicts a temperature change of a control device that controls automatic driving of a vehicle and that is mounted on the vehicle. The cooling execution unit starts cooling the control device based on the temperature change predicted by the prediction unit.

In the cooling execution devices, when the prediction result that a temperature of the control device becomes higher than a predetermined threshold, the cooling execution unit starts cooling the control device.

In any of the cooling execution devices, the prediction unit predicts the temperature change of the control device by AI. The cooling execution device includes a model storage unit that stores a learning model in which information acquired by the control device is used as input and a temperature change of the control device is used as output, the learning model being generated by machine learning using, as learning data, the information acquired by the control device and the temperature change of the control device at a time when the control device acquires the information, and an information acquisition unit that acquires the information acquired by the control device, the prediction unit predicts the temperature change of the control device by inputting the information acquired by the information acquisition unit to the learning model. The information acquisition unit acquires sensor information acquired by the control device from a sensor mounted on the vehicle from the sensor or the control device. The information acquisition unit acquires, from the control device, an analysis result obtained by the control device analyzing a captured image captured by a camera mounted on the vehicle. The information acquisition unit acquires external information received by the control device from an external device from the external device or the control device. The information acquisition unit acquires traffic information on a road where the vehicle is located, received by the control device from the external device from the external device or the control device.

In any of the cooling execution devices, the cooling execution unit starts cooling the control device by using one or a plurality of coolers selected from a plurality of types of coolers in accordance with a level of a temperature of the control device predicted by the prediction unit. The plurality of types of coolers includes a plurality of one or a plurality of types of air coolers, one or a plurality of types of water coolers, and a liquid nitrogen cooler. The prediction unit predicts a temperature change of each of a plurality of portions of the control device, and the cooling execution unit starts cooling the control device by using a cooler selected from a plurality of coolers each of which cools each of the plurality of portions of the control device based on a prediction result from the prediction unit. The control device includes a plurality of processing chips arranged at different positions of the control device, and each of the plurality of coolers is arranged at a position of each of the plurality of processing chips.

An aspect of an embodiment provided a program causing a computer to function as the cooling execution device.

An aspect of an embodiment provided a cooling execution method to be executed by a computer. The cooling execution method includes a prediction stage of predicting a temperature change of a control device that controls automatic driving of a vehicle and that is mounted on the vehicle. The cooling execution method includes a cooling execution stage of starting cooling the control device based on the temperature change predicted in the prediction stage.

An aspect of an embodiment provided a cooling system. The cooling system includes a server and a cooling execution device, the server includes an information acquisition unit that acquires, from the cooling execution device, position information on a vehicle including the cooling execution device and temperature information on a control device of the vehicle, and a prediction unit that predicts a temperature change of the control device based on position information on a vehicle including the cooling execution device and temperature information on a control device of the vehicle, which have been acquired by the information acquisition unit, and the cooling execution device includes an information acquisition unit that acquires, from the server, a prediction result of a temperature change of the control device predicted by the prediction unit of the server, and a cooling execution unit that starts cooling the control device based on the prediction result of a temperature change of the control device acquired by the information acquisition unit.

The server further includes a creation unit that creates a map representing relation between a position of a vehicle and a temperature of a control device from position information on the vehicle including the cooling execution device and temperature information on the control device of the vehicle, which have been acquired by the information acquisition unit, and the prediction unit predicts a temperature change of the control device based on position information of a vehicle including the cooling execution device, temperature information on a control device of the vehicle, and a map representing relation between a position of the vehicle and a temperature of the control device created by the creation unit, the position information and the temperature information having been acquired by the information acquisition unit.

The information acquisition unit of the server acquires, from the cooling execution device, position information on a vehicle including the cooling execution device, temperature information on a control device of the vehicle, and information on a type of the vehicle, the creation unit creates a map representing relation between a position of the vehicle in the type of the vehicle and a temperature of the control device from position information on a vehicle including the cooling execution device, temperature information on a control device of the vehicle, and information on a type of a vehicle, which have been acquired by the information acquisition unit, and the prediction unit of the server predicts a temperature change of the control device based on position information on a vehicle including the cooling execution device, temperature information on a control device of the vehicle, and a map representing relation between a position of the vehicle in the type of the vehicle and a temperature of the control device created by the creation unit, the position information and the temperature information having been acquired by the information acquisition unit.

The cooling execution unit starts cooling the control device a predetermined time before the control device starts heat generation by using a prediction result of a temperature change of the control device acquired by the information acquisition unit.

The cooling execution unit starts cooling the control device by using one or a plurality of coolers selected from a plurality of types of coolers in accordance with a temperature change of the control device by using a prediction result of a temperature change of the control device acquired by the information acquisition unit.

The plurality of types of coolers includes a plurality of one or a plurality of types of air coolers, one or a plurality of types of water coolers, and a liquid nitrogen cooler.

An aspect of an embodiment provided a cooling execution method to be executed by a server and a cooling execution device. The cooling execution method includes an information acquisition process in which the server acquires, from the cooling execution device, position information on a vehicle including the cooling execution device and temperature information on a control device of the vehicle. The cooling execution method includes a prediction process in which the server predicts a temperature change of the control device based on position information on a vehicle including the cooling execution device and temperature information on a control device of the vehicle, which have been acquired in the information acquisition process. The cooling execution method includes an information acquisition process in which the cooling execution device acquires, from the server, a prediction result of a temperature change of the control device predicted in the prediction process of the server. The cooling execution method includes a cooling execution process in which the cooling execution device starts cooling the control device based on prediction of a temperature change of the control device acquired in the information acquisition process.

An aspect of an embodiment provides a cooling program includes a program to be executed by a server, and a program to be executed by a cooling execution device. The cooling program causes the server to execute an information acquisition step of acquiring, from the cooling execution device, position information on a vehicle including the cooling execution device and temperature information on a control device of the vehicle, and a prediction step of predicting a temperature change of the control device based on position information on a vehicle including the cooling execution device and temperature information on a control device of the vehicle, which have been acquired in the information acquisition step, and causes the cooling execution device to execute an information acquisition step of acquiring, from the server, a prediction result of a temperature change of the control device predicted in the prediction step of the server, and a cooling execution step of starting cooling the control device based on the prediction result of a temperature change of the control device acquired in the information acquisition step.

An aspect of an embodiment provides a cooling system. The cooling system includes a server, and a cooling execution device, the server includes an information acquisition unit that acquires, from the cooling execution device, position information on a vehicle including the cooling execution device, temperature information on a control device of the vehicle, an information on a traffic situation, and weather information, and a prediction unit that predicts a temperature change of the control device based on the position information on a vehicle including the cooling execution device, the temperature information on a control device of the vehicle, the information on a traffic situation, and the weather information, which have been acquired by the information acquisition unit, and the cooling execution device includes an information acquisition unit that acquires, from the server, a prediction result of a temperature change of the control device predicted by the prediction unit of the server, and a cooling execution unit that starts cooling the control device based on the prediction result of a temperature change of the control device acquired by the information acquisition unit.

The server further includes a creation unit that creates a map representing relation between a position of a vehicle including the cooling execution device, the information on a traffic situation, the weather information, and a temperature of a control device from position information on the vehicle, temperature information on the control device of the vehicle, the information on a traffic situation, and the weather information, which have been acquired by the information acquisition unit, and the prediction unit predicts a temperature change of the control device based on the position information on the vehicle including the cooling execution device, the temperature information on the control device of the vehicle, the information on a traffic situation, the weather information, and the map representing the relation between the position of the vehicle, the information on a traffic situation, the weather information, and the temperature of the control device created by the creation unit, the position information, the temperature information, the information on a traffic situation, and the weather information having been acquired by the information acquisition unit.

The creation unit creates a map representing relation between a position of a vehicle including the cooling execution device and a temperature of a control device for each of the information on a traffic situation and the weather information from position information on the vehicle, temperature information on the control device of the vehicle, the information on a traffic situation, and the weather information, which have been acquired by the information acquisition unit.

The information acquisition unit of the server further acquires, from the cooling execution device, information on a type of the vehicle, and the creation unit creates a map representing relation between a position of the vehicle, the information on a traffic situation, the weather information, the type of the vehicle, and a temperature of the control device from the position information on the vehicle including the cooling execution device, the temperature information on the control device of the vehicle, the information on a traffic situation, the weather information, and the information on the type of the vehicle.

The cooling execution unit starts cooling the control device a predetermined time before the control device starts heat generation by using a prediction result of a temperature change of the control device acquired by the information acquisition unit.

The cooling execution unit starts cooling the control device by using one or a plurality of coolers selected from a plurality of types of coolers in accordance with a temperature change of the control device by using a prediction result of a temperature change of the control device acquired by the information acquisition unit.

The plurality of types of coolers includes a plurality of one or a plurality of types of air coolers, one or a plurality of types of water coolers, and a liquid nitrogen cooler.

An aspect of an embodiment provides a cooling execution method to be executed by a server and a cooling execution device. The cooling execution method includes an information acquisition process in which the server acquires, from the cooling execution device, position information on a vehicle including the cooling execution device, temperature information on a control device of the vehicle, information on a traffic situation, and weather information. The cooling execution method includes a prediction process in which the server predicts a temperature change of the control device based on position information on a vehicle including the cooling execution device, temperature information on a control device of the vehicle, the information on a traffic situation, and the weather information, which have been acquired in the information acquisition process. The cooling execution method includes an information acquisition process in which the cooling execution device acquires, from the server, a prediction result of a temperature change of the control device predicted in the prediction process of the server. The cooling execution method includes a cooling execution process in which the cooling execution device starts cooling the control device based on prediction of a temperature change of the control device acquired in the information acquisition process.

An aspect of an embodiment provides a cooling program includes a program to be executed by a server, and a program to be executed by a cooling execution device. The cooling program causes the server to execute an information acquisition step of acquiring, from the cooling execution device, position information on a vehicle including the cooling execution device and temperature information on a control device of the vehicle, and a prediction step of predicting a temperature change of the control device based on position information on a vehicle including the cooling execution device, temperature information on a control device of the vehicle, information on a traffic situation, and weather information, which have been acquired in the information acquisition step, and causing the cooling execution device to execute an information acquisition step of acquiring, from the server, a prediction result of a temperature change of the control device predicted in the prediction step of the server, and a cooling execution step of starting cooling the control device based on the prediction result of a temperature change of the control device acquired in the information acquisition step.

An aspect of an embodiment provides a cooling system includes a server, and a cooling execution device.

The server includes an information acquisition unit that acquires, from the cooling execution device, position information on each integrated circuit in a control device, information on processing of each integrated circuit, and information on a driving situation of a vehicle, and a prediction unit that predicts a temperature change at each position of the control device based on the position information on each integrated circuit in the control device, the information on processing of each integrated circuit, and the information on a driving situation of the vehicle, which have been acquired by the information acquisition unit, and the cooling execution device includes an information acquisition unit that acquires, from the server, a prediction result of a temperature change at each position of the control device predicted by the prediction unit of the server, and a cooling execution unit that starts cooling the control device based on the prediction result of a temperature change at each position of the control device acquired by the information acquisition unit.

The prediction unit predicts a temporal temperature change at each position of the control device from position information on each integrated circuit in the control device, information on processing of each integrated circuit, and information on a driving situation of the vehicle, which have been acquired by the information acquisition unit.

The cooling execution unit starts cooling a position where the control device is generating heat by using a prediction result of a temperature change at each position of the control device acquired by the information acquisition unit.

The cooling execution unit starts cooling a position where the control device is generating heat a predetermined time before the control device starts heat generation by using a prediction result of a temperature change at each position of the control device acquired by the information acquisition unit.

The cooling execution unit starts cooling the control device by using one or a plurality of coolers selected from a plurality of types of coolers in accordance with a temperature change at each position of the control device by using a prediction result of a temperature change at each position of the control device acquired by the information acquisition unit.

The plurality of types of coolers includes a plurality of one or a plurality of types of air coolers, one or a plurality of types of water coolers, and a liquid nitrogen cooler.

An aspect of an embodiment provides a cooling method to be executed by a server and a cooling execution device. The cooling method includes an information acquisition process in which the server acquires, from the cooling execution device, position information on each integrated circuit in a control device, information on processing of each integrated circuit, and information on a driving situation of a vehicle. The cooling method includes a prediction process in which the server predicts a temperature change at each position of the control device based on the position information on each integrated circuit in the control device, the information on processing of each integrated circuit, and the information on a driving situation of the vehicle, which have been acquired in the information acquisition process. The cooling method includes an information acquisition process in which the cooling execution device acquires, from the server, a prediction result of a temperature change at each position of the control device predicted in the prediction process of the server. The cooling method includes a cooling execution process in which the cooling execution device starts cooling the control device based on the prediction result of a temperature change at each position of the control device acquired in the information acquisition process.

An aspect of an embodiment provides a cooling program includes a program to be executed by a server, and a program to be executed by a cooling execution device. The cooling program causes the server to execute an information acquisition step of acquiring, from the cooling execution device, position information on each integrated circuit in the control device, information on processing of each integrated circuit, and information on a driving situation of a vehicle, and a prediction step of predicting a temperature change at each position of the control device from the position information on each integrated circuit in the control device, the information on processing of each integrated circuit, and the information on a driving situation of the vehicle, which have been acquired in the information acquisition step, and causing the cooling execution device to execute an information acquisition step of acquiring, from the server, a prediction result of a temperature change at each position of the control device predicted in the prediction step of the server, and a cooling execution step of starting cooling the control device based on the prediction result of a temperature change at each position of the control device acquired in the information acquisition step.

An aspect of an embodiment provides a cooling execution device. The cooling execution device includes a detection unit that detects a temperature of a control device that controls automatic driving of a vehicle and that is mounted on the vehicle, and a cooling execution unit that cools the control device by using a predetermined cooler based on a time when the temperature detected by the detection unit continues to be a predetermined temperature or more.

In the cooling execution devices, when the time when the predetermined temperature or more continues exceeds a predetermined threshold, the cooling execution unit executes cooling by using the cooler including a plurality of one or a plurality of types of air coolers, one or a plurality of types of water coolers, and a liquid nitrogen cooler.

In the cooling execution devices, when the temperature exceeds a predetermined threshold, the cooling execution unit executes rapid cooling.

In the cooling execution devices, the cooling execution device further includes a prediction unit that predicts a temperature change of a control device that controls automatic driving of a vehicle and that is mounted on the vehicle, the cooling execution unit executes cooling by using the cooler based on the time when the predetermined temperature or more continues as the temperature change predicted by the prediction unit.

In the cooling execution devices, the cooling execution device further includes a prediction unit that predicts a temperature change of each of a plurality of portions of the control device, the cooling execution unit starts cooling the control device by using a cooler selected from a plurality of coolers each of which cools each of the plurality of portions of the control device based on a prediction result from the prediction unit.

The control device includes a plurality of processing chips arranged at different positions of the control device, and each of the plurality of coolers is arranged at a position of each of the plurality of processing chips.

An aspect of an embodiment provides a cooling execution program causing a computer to function as the cooling execution device.

According to an aspect of an embodiment, a cooling execution method to be executed by a computer, includes a detection stage of detecting a temperature of a control device that controls automatic driving of a vehicle and that is mounted on the vehicle, and a cooling execution stage of cooling the control device by using a predetermined cooler based on a time when the temperature detected in the detection stage continues to be a predetermined temperature or more.

An aspect of an embodiment provides a cooling execution device. The cooling execution device includes an estimation unit that estimates switching between automatic driving and manual driving based on a preset travel route, a creation unit that creates a cooling schedule in which a cooling conditions based on a predetermined cooler is set based on an estimation result of the estimation unit, and a cooling execution unit that cools a control device that controls automatic driving of a vehicle and that is mounted on the vehicle based on the cooling schedule created by the creation unit.

In the cooling execution devices, the estimation unit estimates whether or not switching from the automatic driving to the manual driving occurs based on a road condition of the travel route.

In the cooling execution devices, when the estimation unit estimates that the automatic driving is switched to the manual driving, the creation unit creates the cooling schedule in which a cooler is set for a travel section of the manual driving, and when the estimation unit estimates that the manual driving is switched to the automatic driving, the creation unit creates the cooling schedule in which a cooler is set for a travel section of the automatic driving.

In the cooling execution devices, the cooling execution device further includes a detection unit that detects a temperature change of a control device that controls automatic driving of a vehicle and that is mounted on the vehicle, and a prediction unit that predicts a temperature change of the control device, the creation unit compares an actual temperature change detected by the detection unit with a predicted temperature change predicted by the prediction unit, and, when the predicted temperature change exceeds the actual temperature change, creates the cooling schedule in which the predetermined cooler is set.

In the cooling execution devices, the cooler includes a plurality of one or a plurality of types of air coolers, one or a plurality of types of water coolers, and a liquid nitrogen cooler.

In the cooling execution devices, the cooling execution device further includes a prediction unit that predicts a temperature change of a control device that controls automatic driving of a vehicle and that is mounted on the vehicle, the cooling execution unit cools the control device by using a cooler selected from a plurality of coolers each of which cools each of a plurality of portions of the control device based on the cooling schedule created by the creation unit.

The control device includes a plurality of processing chips arranged at different positions of the control device, and each of the plurality of coolers is arranged at a position of each of the plurality of processing chips.

An aspect of an embodiment provides a program causing a computer to function as the cooling execution device.

According to an aspect of an embodiment, a cooling execution method to be executed by a computer, includes an estimation stage of estimating switching between automatic driving and manual driving based on a preset travel route, a creation stage of creating a cooling schedule in which a cooling condition based on a predetermined cooler is set based on an estimation result in the estimation stage, and a cooling execution stage of cooling a control device that controls automatic driving of a vehicle and that is mounted on the vehicle based on the cooling schedule created in the creation stage.

An aspect of an embodiment provides a cooling device including a prediction unit that predicts a temperature change of a control device that controls automatic driving of a vehicle and that is mounted on the vehicle, and a cooling execution unit that performs cooling so that a temperature of the control device is held within a predetermined temperature range based on the temperature change predicted by the prediction unit.

In addition, the cooling execution unit determines the predetermined temperature range in accordance with a threshold temperature preliminarily determined for the control device.

Furthermore, the prediction unit predicts the temperature change of the control device by AI.

In addition, the cooling device further includes a model storage unit that stores a learning model in which information acquired by the control device is used as input and a temperature change of the control device is used as output, the learning model being generated by machine learning using, as learning data, the information acquired by the control device and the temperature change of the control device at a time when the control device acquires the information, and an information acquisition unit that acquires the information acquired by the control device, the prediction unit predicts the temperature change of the control device by inputting the information acquired by the information acquisition unit to the learning model. The information acquisition unit acquires sensor information acquired by the control device from a sensor mounted on the vehicle from the sensor or the control device.

Furthermore, the information acquisition unit acquires, from the control device, an analysis result obtained by the control device analyzing a captured image captured by a camera mounted on the vehicle.

In addition, the information acquisition unit acquires external information received by the control device from an external device from the external device or the control device. The information acquisition unit acquires traffic information on a road where the vehicle is located, received by the control device from the external device from the external device or the control device.

Furthermore, the cooling execution unit starts cooling the control device by using one or a plurality of coolers selected from a plurality of types of coolers in accordance with a level of a temperature of the control device predicted by the prediction unit.

In addition, the plurality of types of coolers in the cooling execution unit includes a plurality of one or a plurality of types of air coolers, one or a plurality of types of water coolers, and a liquid nitrogen cooler.

Furthermore, the prediction unit predicts a temperature change of each of a plurality of portions of the control device, and the cooling execution unit starts cooling the control device by using a cooler selected from a plurality of coolers each of which cools each of the plurality of portions of the control device based on a prediction result from the prediction unit.

In addition, the control device includes a plurality of processing chips arranged at different positions of the control device, and each of the plurality of coolers is arranged at a position of each of the plurality of processing chips.

An aspect of an embodiment provides a cooling method to be executed by a cooling device, including a prediction process of predicting a temperature change of a control device that controls automatic driving of a vehicle and that is mounted on the vehicle, and a cooling execution process of performing cooling so that a temperature of the control device is held within a predetermined temperature range based on the temperature change predicted in the prediction process.

An aspect of an embodiment provides a cooling program causing a computer to execute a prediction procedure of predicting a temperature change of a control device that controls automatic driving of a vehicle and that is mounted on the vehicle, and a cooling execution procedure of performing cooling so that a temperature of the control device is held within a predetermined temperature range based on the temperature change predicted in the prediction procedure.

An aspect of an embodiment provides a cooling execution device. The cooling execution device includes a detection unit that detects a temperature change of a control device that controls automatic driving of a vehicle and that is mounted on the vehicle, a selection unit that selects a predetermined driving condition for lowering a temperature of the control device when the temperature change exceeds a predetermined threshold, and an output unit that outputs the predetermined driving condition based on a result of selection of the selection unit.

In the cooling execution devices, the selection unit selects a driving condition for inhibiting a calculation amount related to predetermined information processing of the control device as the predetermined driving condition when the temperature change exceeds a predetermined threshold.

In the cooling execution devices, the cooling execution device further includes an information acquisition unit that acquires a result of information processing related to the automatic driving from an external information processing device that performs the information processing related to the automatic driving as predetermined information processing of the control device.

In the cooling execution devices, the selection unit selects a driving condition for inhibiting a driving speed of the automatic driving to a predetermined speed or less as the predetermined driving condition when the temperature change exceeds a predetermined threshold.

In the cooling execution devices, the selection unit selects a driving condition for changing the automatic driving to manual driving as the predetermined driving condition when the temperature change exceeds a predetermined threshold.

In the cooling execution devices, the selection unit selects a driving condition for stopping at a predetermined position of a road included in a travel route of the automatic driving as the predetermined driving condition when the temperature change exceeds a predetermined threshold.

In the cooling execution devices, the selection unit selects a driving condition for inhibiting acquisition of predetermined information to be used for information processing of the automatic driving as the predetermined driving condition when the temperature change exceeds a predetermined threshold.

An aspect of an embodiment provides a program causing a computer to function as the cooling execution device.

According to an aspect of an embodiment, a cooling execution method to be executed by a computer, includes a detection stage of detecting a temperature change of a control device that controls automatic driving of a vehicle and that is mounted on the vehicle, a selection stage of selecting a predetermined driving condition for lowering a temperature of the control device when the temperature change exceeds a predetermined threshold, and an output stage of outputting the predetermined driving condition based on a result of selection in the selection stage.

An aspect of an embodiment provides a cooling device including a prediction unit that predicts a temperature change of a control device that controls automatic driving of a vehicle and that is mounted on the vehicle, a communication unit that communicates with another vehicle within a predetermined range based on the temperature change predicted by the prediction unit, and an instruction unit that instructs the control device to execute arithmetic related to control of automatic driving of the other vehicle with which the communication unit communicates.

In addition, the communication unit determines another vehicle within a range in which communication with the other vehicle is allowed to be maintained for a predetermined time as a vehicle within the predetermined range, and communicate with the vehicle.

Furthermore, the cooling device further includes a cooling execution unit that starts cooling the control device based on the temperature change predicted by the prediction unit.

In addition, when the prediction unit predicts that a temperature of the control device becomes higher than a predetermined threshold, the cooling execution unit starts cooling the control device.

Furthermore, the prediction unit predicts the temperature change of the control device by AI.

In addition, the automatic driving control device further includes a model storage unit that stores a learning model in which information acquired by the control device is used as input and a temperature change of the control device is used as output, the learning model being generated by machine learning using, as learning data, the information acquired by the control device and the temperature change of the control device at a time when the control device acquires the information, and an information acquisition unit that acquires the information acquired by the control device, the prediction unit predicts the temperature change of the control device by inputting the information acquired by the information acquisition unit to the learning model.

Furthermore, the information acquisition unit acquires sensor information acquired by the control device from a sensor mounted on the vehicle from the sensor or the control device.

In addition, the information acquisition unit acquires, from the control device, an analysis result obtained by the control device analyzing a captured image captured by a camera mounted on the vehicle.

Furthermore, the information acquisition unit acquires external information received by the control device from an external device from the external device or the control device. The information acquisition unit acquires traffic information on a road where the vehicle is located, received by the control device from the external device from the external device or the control device.

In addition, the cooling execution unit starts cooling the control device by using one or a plurality of coolers selected from a plurality of types of coolers in accordance with a level of a temperature of the control device predicted by the prediction unit.

Furthermore, in the cooling execution unit, the plurality of types of coolers includes a plurality of one or a plurality of types of air coolers, one or a plurality of types of water coolers, and a liquid nitrogen cooler.

In addition, the prediction unit predicts a temperature change of each of a plurality of portions of the control device, and the cooling execution unit starts cooling the control device by using a cooler selected from a plurality of coolers each of which cools each of the plurality of portions of the control device based on a prediction result from the prediction unit.

Furthermore, the control device includes a plurality of processing chips arranged at different positions of the control device, and each of the plurality of coolers is arranged at a position of each of the plurality of processing chips.

An aspect of an embodiment provides a cooling method to be executed by a cooling device, including a prediction process of predicting a temperature change of a control device that controls automatic driving of a vehicle and that is mounted on the vehicle, a communication process of communicating with another vehicle within a predetermined range based on the temperature change predicted in the prediction process, and an instruction process of instructing the control device to execute arithmetic related to control of automatic driving of the other vehicle with which communication is performed in the communication process.

An aspect of an embodiment provides a cooling program causing a computer to execute a prediction procedure of predicting a temperature change of a control device that controls automatic driving of a vehicle and that is mounted on the vehicle, a communication procedure of communicating with another vehicle within a predetermined range based on the temperature change predicted in the prediction procedure, and an instruction procedure of instructing the control device to execute arithmetic related to control of automatic driving of the other vehicle with which communication is performed in the communication procedure.

An aspect of an embodiment provides a cooling execution device. The cooling execution device includes a prediction unit that predicts a change of computing power of a control device that controls automatic driving of a vehicle and that is mounted on the vehicle. The cooling execution device includes a cooling execution unit that starts cooling the control device based on the change predicted by the prediction unit.

In the cooling execution devices, the prediction unit predicts the change of the computing power of the control device by AI. The prediction unit predicts a moment when the computing power of the control device is maximized, and the cooling execution unit starts cooling the control device based on the moment predicted by the prediction unit. The cooling execution unit starts cooling the control device at the moment when the computing power of the control device is maximized. The prediction unit predicts a time until a temperature of the control device becomes higher than a predetermined temperature from a prediction result of the moment when the computing power of the control device is maximized, and the cooling execution unit starts cooling the control device based on the time predicted by the prediction unit.

In any of the cooling execution device further includes a model storage unit that stores a learning model in which information acquired by the control device is used as input and computing power of the control device is used as output, the learning model being generated by machine learning using, as learning data, the information acquired by the control device and the computing power of the control device at a time when the control device acquires the information, and an information acquisition unit that acquires the information acquired by the control device, and the prediction unit predicts a change of the computing power of the control device by inputting the information acquired by the information acquisition unit to the learning model. The information acquisition unit acquires at least one of sensor information acquired by the control device from a sensor mounted on the vehicle, an analysis result obtained by the control device analyzing a captured image captured by a camera mounted on the vehicle, external information received by the control device from an external device, and traffic information on a road where the vehicle is located, received by the control device from the external device.

In any of the cooling execution device further includes a model storage unit that stores a learning model in which information acquired by the control device is used as input and a time until the control device is cooled in a case where cooling of the control device is started is used as output, the learning model being generated by machine learning using, as learning data, the information acquired by the control device and the time until the control device is cooled in the case where the cooling of the control device is started at a time when the control device acquires the information, and an information acquisition unit that acquires the information acquired by the control device, the cooling execution unit determines timing when cooling of the control device is started based on a change predicted by the prediction unit and the time until the control device is cooled in the case where cooling of the control device is started, the time having been acquired by inputting the information acquired by the information acquisition unit to the learning model.

In any of the cooling execution devices, the cooling execution unit adjusts a degree of cooling of the control device in accordance with a risk rate indicating an establishment that the control device does not normally function due to a high temperature of the control device and a risk of exerting an influence on normal automatic driving of the vehicle occurs. When the risk rate is lower than a first threshold, the cooling execution unit cools the control device with a first cooling intensity, when the risk rate is higher than the first threshold and lower than a second threshold higher than the first threshold, the cooling execution unit cools the control device with a second cooling intensity higher than the first cooling intensity, and, when the risk rate is higher than the second threshold, the cooling execution unit cools the control device with a third cooling intensity higher than the second cooling intensity.

An aspect of an embodiment provides a program causing a computer to function as the cooling execution device.

According to an aspect of an embodiment, a cooling execution method to be executed by a computer, includes a prediction stage of predicting a change of computing power of a control device that controls automatic driving of a vehicle and that is mounted on the vehicle. The cooling execution method includes a cooling execution stage of starting cooling the control device based on the change predicted in the prediction stage.

The above summary of the invention does not list all the necessary features of the invention, and sub-combinations of these feature groups can also be included in the invention.

### BRIEF DESCRIPTION OF DRAWINGS

FIG. 1 schematically illustrates an example of a system 10.

FIG. 2 is an explanatory diagram illustrating a learning phase in the system 10.

FIG. 3 is an explanatory diagram illustrating a cooling execution phase in the system 10.

FIG. 4 schematically illustrates an example of a SoCBox 400 and a cooling unit 600.

FIG. 5 schematically illustrates an example of the SoCBox 400 and the cooling unit 600.

FIG. 6 schematically illustrates an example of the SoCBox 400 and the cooling unit 600.

FIG. 7 schematically illustrates an example of a System 10.

FIG. 8 is an explanatory diagram illustrating a learning phase in the system 10.

FIG. 9 is an explanatory diagram illustrating a cooling execution phase in the system 10.

FIG. 10 schematically illustrates an example of a SoCBox 400 and a cooling unit 600.

FIG. 11 schematically illustrates an example of the SoCBox 400 and the cooling unit 600.

FIG. 12 schematically illustrates an example of the SoCBox 400 and the cooling unit 600.

FIG. 13 schematically illustrates an example of a system 10.

FIG. 14 is an explanatory diagram illustrating a learning phase in the system 10.

FIG. 15 is an explanatory diagram illustrating a cooling execution phase in the system 10.

FIG. 16 schematically illustrates an example of a SoCBox 400 and a cooling unit 600.

FIG. 17 schematically illustrates an example of the SoCBox 400 and the cooling unit 600.

FIG. 18 schematically illustrates an example of the SoCBox 400 and the cooling unit 600.

FIG. 19 schematically illustrates an example of a system 10.

FIG. 20 is an explanatory diagram illustrating a learning phase in the system 10.

FIG. 21 is an explanatory diagram illustrating a cooling execution phase in the system 10.

FIG. 22 schematically illustrates an example of a SoCBox 400 and a cooling unit 600.

FIG. 23 schematically illustrates an example of the SoCBox 400 and the cooling unit 600.

FIG. 24 schematically illustrates an example of the SoCBox 400 and the cooling unit 600.

FIG. 25 schematically illustrates an example of a system 10.

FIG. 26 is an explanatory diagram illustrating a learning phase in the system 10.

FIG. 27 is an explanatory diagram illustrating a cooling execution phase in the system 10.

FIG. 28 schematically illustrates an example of a SoCBox 400 and a cooling unit 600.

FIG. 29 schematically illustrates an example of the SoCBox 400 and the cooling unit 600.

FIG. 30 schematically illustrates an example of the SoCBox 400 and the cooling unit 600.

FIG. 31 schematically illustrates an example of a system 10.

FIG. 32 is an explanatory diagram illustrating a learning phase in the system 10.

FIG. 33 is an explanatory diagram illustrating a cooling execution phase in the system 10.

FIG. 34 schematically illustrates an example of a SoCBox 400 and a cooling unit 600.

FIG. 35 schematically illustrates an example of the SoCBox 400 and the cooling unit 600.

FIG. 36 schematically illustrates an example of the SoCBox 400 and the cooling unit 600.

FIG. 37 schematically illustrates an example of a system 10.

FIG. 38 is an explanatory diagram illustrating a learning phase in the system 10.

FIG. 39 is an explanatory diagram illustrating a cooling execution phase in the system 10.

FIG. 40 schematically illustrates an example of a SoCBox 400 and a cooling unit 600.

FIG. 41 schematically illustrates an example of the SoCBox 400 and the cooling unit 600.

FIG. 42 schematically illustrates an example of the SoCBox 400 and the cooling unit 600.

FIG. 43 schematically illustrates an example of a system 10.

FIG. 44 is an explanatory diagram illustrating a learning phase in the system 10.

FIG. 45 is an explanatory diagram illustrating a cooling execution phase in the system 10.

FIG. 46 schematically illustrates an example of a SoCBox 400 and a cooling unit 600.

FIG. 47 schematically illustrates an example of the SoCBoX 400 and the cooling unit 600.

FIG. 48 schematically illustrates an example of the SoCBox 400 and the cooling unit 600.

FIG. 49 schematically illustrates an example of a system 10.

FIG. 50 is an explanatory diagram of a state in which communication is performed between vehicles in an embodiment.

FIG. 51 is an explanatory diagram illustrating a learning phase in the system 10.

FIG. 52 is an explanatory diagram illustrating a cooling execution phase in the system 10.

FIG. 53 schematically illustrates an example of a SoCBox 400 and a cooling unit 600.

FIG. 54 schematically illustrates an example of the SoCBox 400 and the cooling unit 600.

FIG. 55 schematically illustrates an example of the SoCBox 400 and the cooling unit 600.

FIG. 56 schematically illustrates an example of a system 10.

FIG. 57 is an explanatory diagram illustrating a learning phase in the system 10.

FIG. 58 is an explanatory diagram illustrating a cooling execution phase in the system 10.

FIG. 59 schematically illustrates an example of a SoCBox 400 and a cooling unit 600.

FIG. 60 schematically illustrates an example of the SoCBox 400 and the cooling unit 600.

FIG. 61 schematically illustrates an example of the SoCBox 400 and the cooling unit 600.

FIG. 62 schematically illustrates an example of a hardware configuration of a computer 1200 that functions as a management server 100, a SoCBox 400, a cooling execution device 500, or a cooling device 700.

### DESCRIPTION OF EMBODIMENTS

Although the present invention will be described below through embodiments of the invention, the following embodiments do not limit the invention according to claims. Furthermore, not all combinations of features described in the embodiments are essential to the solution of the invention.

### First Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

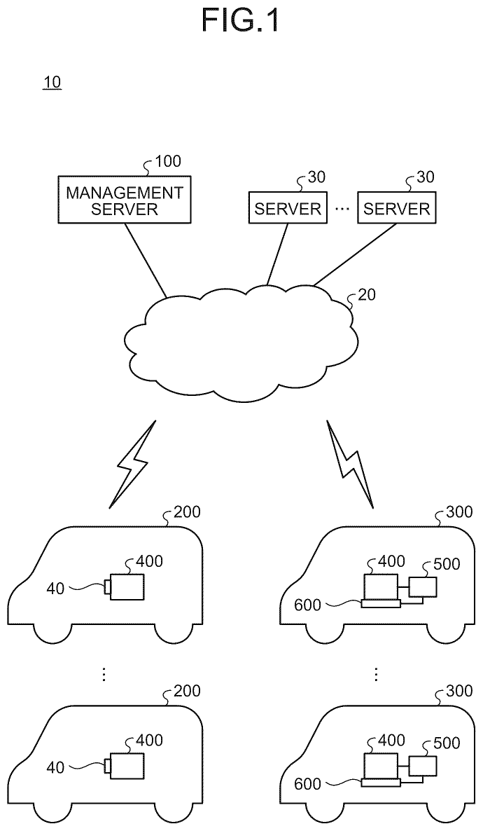

FIG. 1 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 controls automatic driving of the vehicle by using sensor values of a plurality of sensors mounted on the vehicle. An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The cooling execution device 500 according to the embodiment predicts a temperature change of the SoCBox 400, and starts cooling the SoCBox 400 based on the temperature change. For example, when predicting that the SoCBox 400 is starting heat generation, the cooling execution device 500 immediately starts cooling the SoCBox 400 accordingly. The SoCBox 400 can be reliably prevented from having high temperature by starting cooling earlier than or simultaneously with the start of heat generation.

Furthermore, energy required for cooling can be reduced as compared with that in a case where the SoCBox 400 is constantly cooled.

The cooling execution device 500 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

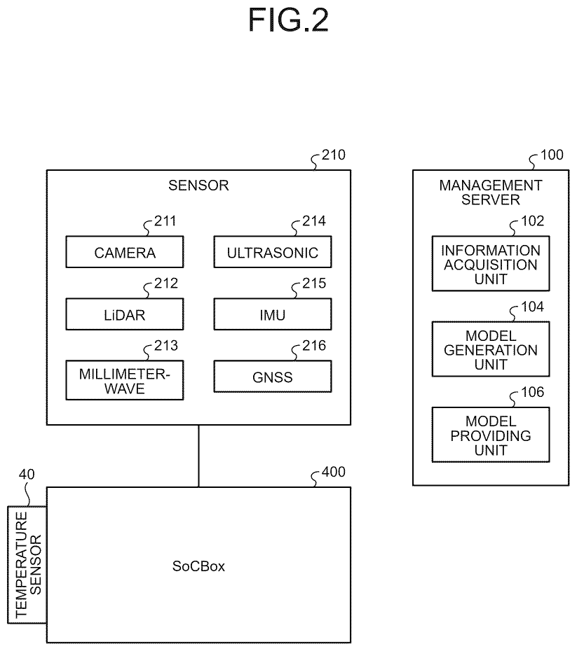

FIG. 2 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

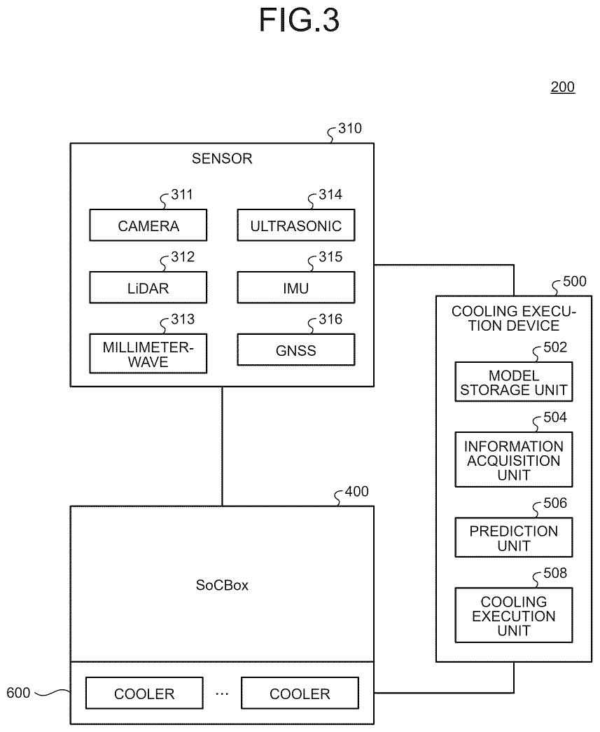

FIG. 3 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling execution device 500 includes a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

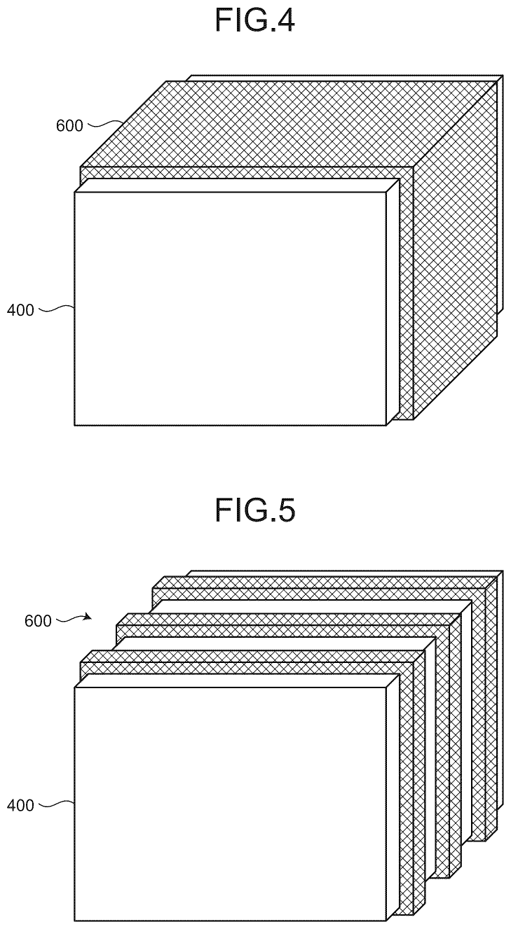

FIG. 4 schematically illustrates an example of the SoCBox 400 and the cooling unit 600. FIG. 4 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 5 schematically illustrates an example of the SoCBox 400 and the cooling unit 600. FIG. 5 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

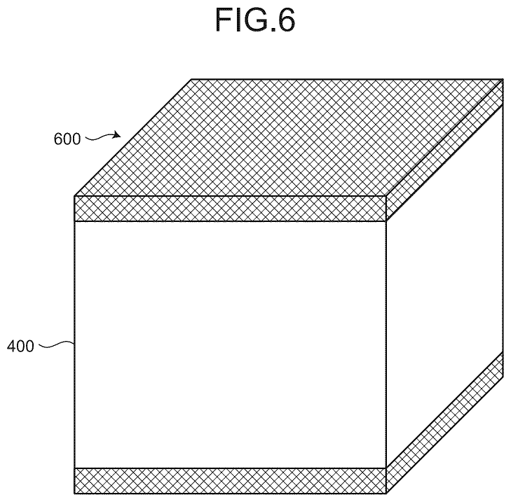

FIG. 6 schematically illustrates an example of the SoCBox 400 and the cooling unit 600. FIG. 6 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SocBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Second Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

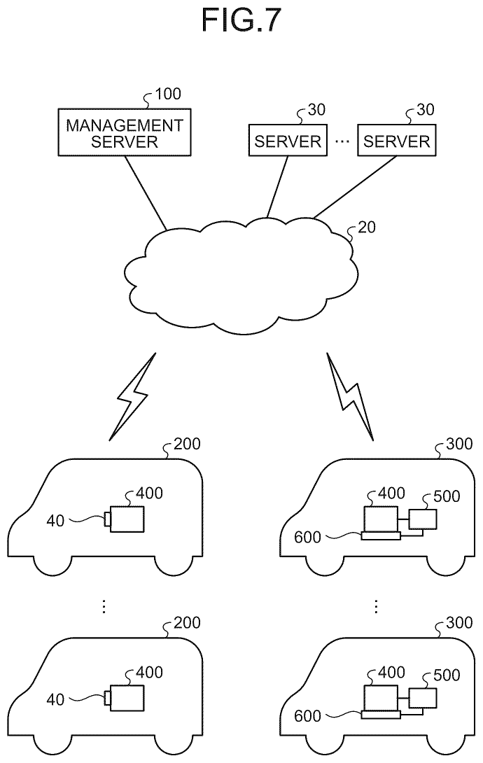

FIG. 7 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 is a control device that controls automatic driving of the vehicle by using sensor values of a plurality of sensors mounted on the vehicle. An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The system 10 according to the embodiment predicts a temperature change of the SoCBox 400 based on position information on the vehicle including the cooling execution device 500 and temperature information on the SoCBox 400 of the vehicle, and starts cooling the SoCBox 400 based on the temperature change. For example, the system 10 preliminarily predicts heat generation in a place where a processing amount increases to easily cause heat generation of the SoCBox 400, such as a city area where there are many vehicles and pedestrians, and immediately starts cooling the SoCBox 400. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The system 10 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model. Furthermore, the cooling execution device 500 may receive information on the type of the vehicle 300 from the server 30, and store the information. Note that the information on the type of the vehicle 300 may include information such as the type of the vehicle 300, information on a vehicle type and heat generation of the SoCBox 400, and a parameter for each of vehicle types. Here, the parameter for each of vehicle types includes information such as information on a vehicle type in which the SoCBox 400 easily generates heat, information on a vehicle type in which the SoCBox 400 does not easily generate heat, and information on a mountable cooler for each of vehicle types.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400. Furthermore, the cooling execution device 500 can perform processing similar to prediction processing performed by the management server 100 to be described later.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

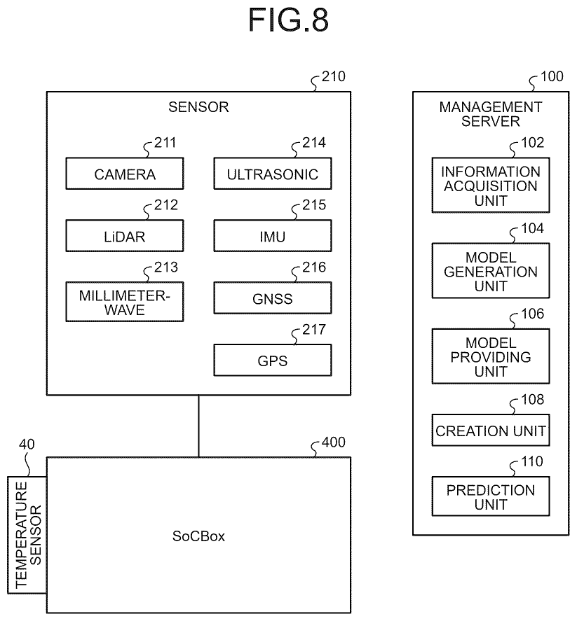

FIG. 8 is an explanatory diagram illustrating a learning phase in the system 10. Here, the sensor 210 mounted on the vehicle 200 is illustrated as including the camera 211, the light detection and ranging (LiDAR) 212, the millimeter-wave sensor 213, the ultrasonic sensor 214, the IMU sensor 215, the global navigation satellite system (GNSS) sensor 216, and a global positioning system (GPS) sensor 217. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes the information acquisition unit 102, the model generation unit 104, the model providing unit 106, a creation unit 108, and a prediction unit 110.

The information acquisition unit 102 acquires various pieces of information. For example, the information acquisition unit 102 acquires, from the cooling execution device 500, position information on the vehicle 300 including the cooling execution device 500 and temperature information on the SoCBox 400 of the vehicle 300. Furthermore, the information acquisition unit 102 acquires, from the cooling execution device 500, the position information on the vehicle 300 including the cooling execution device 500, the temperature information on the SoCBox 400 of the vehicle 300, and information on the type of the vehicle 300. Note that the position information may be acquired from the GNSS sensor or the GPS sensor. Furthermore, the position information may include information on a travel route and a destination of the vehicle 300. Note that the information acquisition unit 102 may acquire various pieces of information at predetermined timing or cycle. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The creation unit 108 creates a map representing the relation between the position of the vehicle 300 and the temperature of the SoCBox 400 from the position information on the vehicle 300 including the cooling execution device 500 and the temperature information on the SoCBox 400 of the vehicle 300, which have been acquired by the information acquisition unit 102. Furthermore, the creation unit 108 creates a map representing the relation between the position of the vehicle 300 and the temperature of the SoCBox 400 for each type of the vehicle 300 from the position information on the vehicle 300 including the cooling execution device 500, the temperature information on the SoCBox 400 of the vehicle 300, and information on the type of the vehicle 300, which have been acquired by the information acquisition unit 102.

The prediction unit 110 predicts the temperature change of the SoCBox 400 based on the position information on the vehicle 300 including the cooling execution device 500 and the temperature information on the SoCBox 400 of the vehicle 300, which have been acquired by the information acquisition unit 102. In the case, the prediction unit 110 may perform prediction by using the position information on the vehicle 300 including the cooling execution device 500 and the temperature information on the SoCBox 400 of the vehicle 300, which have been acquired in the past by the information acquisition unit 102.

For example, the prediction unit 110 predicts the temperature change of the SoCBox 400 based on the position information on the vehicle including the cooling execution device 500 acquired by the information acquisition unit 102 and the temperature information on the SoCBox 400 of the vehicle 300, which have been acquired by the information acquisition unit 102, by using the position information on the vehicle 300 including the cooling execution device 500 and the temperature information on the SoCBox 400 of the vehicle 300, which have been accumulated. For example, in a case of position information on the vehicle 300 of a city area, the prediction unit 110 predicts the temperature change based on the fact that a heat generation amount increases by approximately 20% from data indicating that the heat generation amount increases by approximately 20% in an urban area as compared to that at a usual time in information acquired in the past.

Furthermore, the prediction unit 110 predicts the temperature change of the SoCBox 400 based on the position information on the vehicle 300 including the cooling execution device 500, the temperature information on the SoCBox 400 of the vehicle 300, and the map representing the relation between the position of the vehicle 300 and the temperature of the SoCBox 400. The position information and the temperature information have been acquired by the information acquisition unit 102. The map has been created by the creation unit 108. Furthermore, the prediction unit 110 predicts the temperature change of the SoCBox 400 based on the position information on the vehicle 300 including the cooling execution device 500, the temperature information on the SoCBox 400 of the vehicle 300, and the map representing the relation between the position of the vehicle 300 and the temperature of the SoCBox 400 in the type of the vehicle 300. The position information and the temperature information have been acquired by the information acquisition unit 102. The map has been created by the creation unit 108.

The temperature change of the SoCBox 400 predicted by the prediction unit 110 includes a temporal temperature change of the SoCBox 400 of the vehicle 300.

For example, the prediction unit 110 may predict the temporal temperature change of the SoCBox 400 of the vehicle 300 on a travel route from the current position of the vehicle 300 to a destination.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

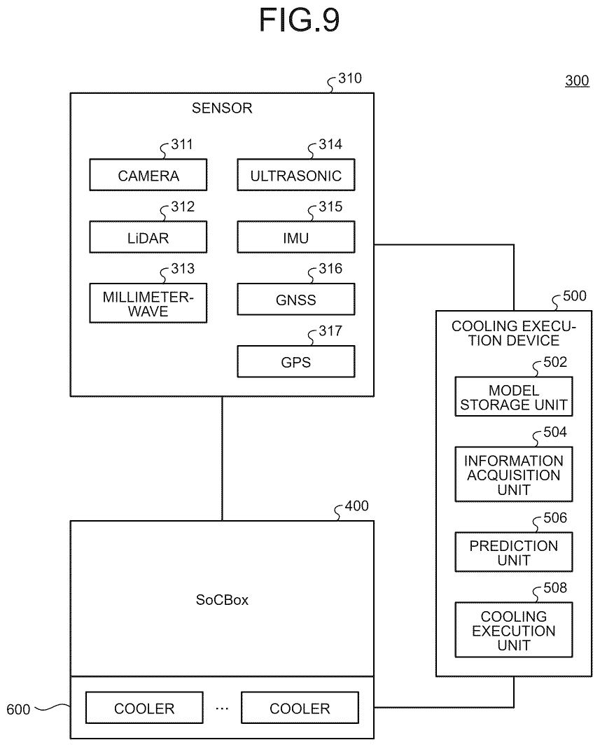

FIG. 9 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, a GNSS sensor 316, and a GPS sensor 317. The vehicle 300 is not required to include all the sensors. The vehicle 300 does not have to include some of the sensors. The vehicle 200 may include a sensor other than the sensors.

The cooling execution device 500 includes a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The information acquisition unit 504 acquires, from the management server 100, a prediction result of the temperature change of the SoCBox 400 predicted by the prediction unit 110 of the management server 100.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502. Furthermore, the prediction unit 506 can perform processing similar to the prediction processing performed by the prediction unit 110 of the management server 100.

The cooling execution unit 508 starts cooling the SoCBox 400 based on the prediction result of the temperature change of the SoCBox 400 acquired by the information acquisition unit 504. For example, the cooling execution unit 508 starts cooling the SoCBox 400 from a predetermined time before the SoCBox 400 starts heat generation by using the prediction result of the temperature change of the SoCBox 400 acquired by the information acquisition unit 504. Furthermore, for example, the cooling execution unit 508 starts cooling the SoCBox 400 from a predetermined time before the timing when the SoCBox 400 is predicted to have a predetermined temperature or more by using the prediction result of the temperature change of the SoCBox 400 acquired by the information acquisition unit 504. Furthermore, for example, the cooling execution unit 508 starts cooling the SoCBox 400 at the timing when a point where the SoCBox 400 is predicted to start heat generation and the current position of the vehicle 300 fall within a predetermined distance by using the prediction result of the temperature change of the SoCBox 400 acquired by the information acquisition unit 504.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 starts cooling the SoCBox 400 by using one or a plurality of coolers selected from a plurality of types of coolers in accordance with the temperature change of the SoCBox 400 by using the prediction result of the temperature change of the SoCBox 400 acquired by the information acquisition unit 504. The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

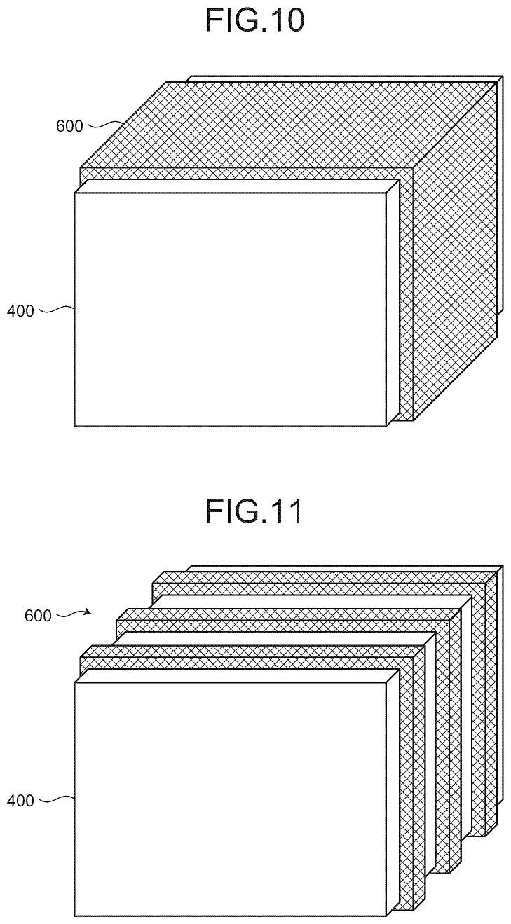

FIG. 10 schematically illustrates an example of the SoCBox 400 and the cooling unit 600. FIG. 10 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 11 schematically illustrates an example of the SoCBox 400 and the cooling unit 600. FIG. 11 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

Furthermore, the cooling execution device 500 of the system 10 starts cooling the SoCBox 400 based on the temperature change of the SoCBox 400 predicted based on the position information on the vehicle 300 and the information on the temperature of the SoCBox 400. The cooling execution device 500 can thereby perform efficient cooling in accordance with the position of the vehicle 300.

Furthermore, the cooling execution device 500 of the system 10 starts cooling the SoCBox 400 based on the temperature change of the SoCBox 400 predicted based on the position information on the vehicle 300, the information on the temperature of the SoCBox 400, and the map representing the relation between the position of the vehicle 300 and the temperature of the SoCBox 400. The cooling execution device 500 can thereby perform efficient cooling in accordance with the position of the vehicle 300.

Furthermore, the cooling execution device 500 of the system 10 starts cooling the SoCBox 400 based on the temperature change of the SoCBox 400 predicted based on the position information on the vehicle 300, the information on the type of the vehicle 300, the information on the temperature of the SoCBox 400, and the map representing the relation between the position of the vehicle 300 and the temperature of the SoCBox 400. The cooling execution device 500 can thereby perform efficient cooling in accordance with the position and type of the vehicle 300.

Furthermore, the cooling execution device 500 of the system 10 starts cooling the SoCBox 400 from a predetermined time before the SoCBox 400 starts heat generation based on the prediction result of the temperature change of the SoCBox 400. The cooling execution device 500 can thereby reduce the possibility of overheating, and perform efficient cooling.

Furthermore, the cooling execution device 500 of the system 10 performs cooling with a plurality of coolers in accordance with the temperature change of the SoCBox 400 by using the prediction result of the temperature change of the SoCBox 400. The cooling execution device 500 can thereby perform efficient cooling suitable for the temperature change.

Furthermore, the cooling execution device 500 of the system 10 performs cooling with a water cooler and a liquid nitrogen cooler in accordance with the temperature change of the SoCBox 400 by using the prediction result of the temperature change of the SoCBox 400. The cooling execution device 500 can thereby perform efficient cooling by using a cooler suitable for the temperature change.

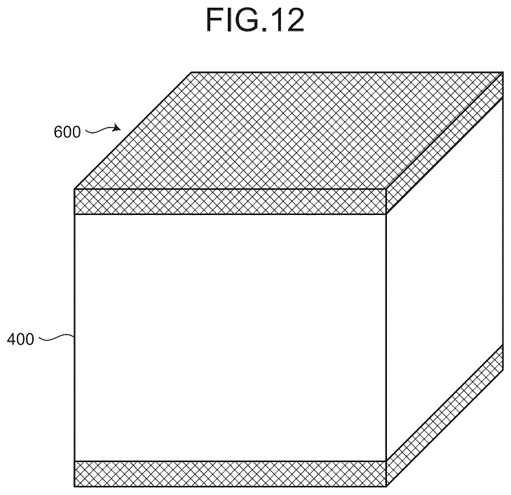

FIG. 12 schematically illustrates an example of the SoCBox 400 and the cooling unit 600. FIG. 12 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Third Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). For example, even if the vehicle is located at the same place, a change in environment such as air temperature, weather, and a traffic situation may change the heat generation amount of the SoCBox, which may cause overheating. This is because a change in a traffic situation and weather increases detection amounts of various sensors and complicates control of automatic driving. In such a case, AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

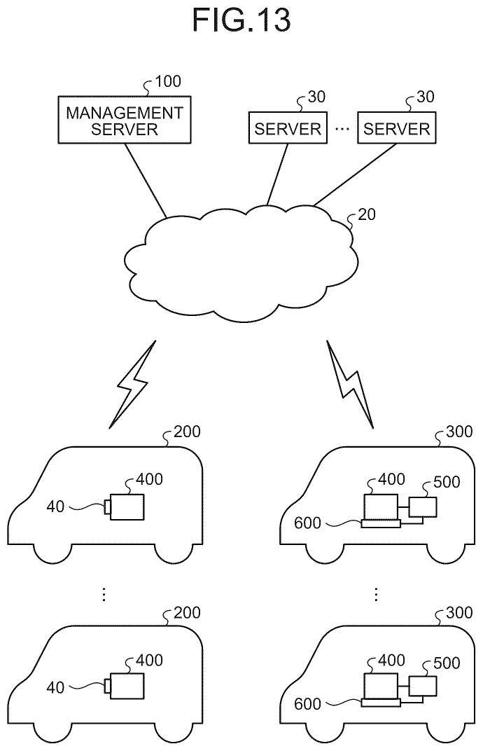

FIG. 13 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 is a control device that controls automatic driving of the vehicle by using sensor values of a plurality of sensors mounted on the vehicle. An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The system 10 according to the embodiment predicts a temperature change of the SoCBox 400 based on position information on the vehicle 300 including the cooling execution device 500, temperature information on the SoCBox 400 of the vehicle 300, information on a traffic situation, and weather information, and starts cooling the SoCBox 400 based on the temperature change. For example, the system 10 preliminarily predicts heat generation from a situation in which a processing amount increases to easily cause heat generation of the SoCBox 400, such as congestion and rainy weather, and immediately starts cooling the SoCBox 400. The SoCBox 400 can be reliably prevented from having high temperature by starting cooling earlier than or simultaneously with the start of heat generation.

Furthermore, energy required for cooling can be reduced as compared with that in a case where the SoCBox 400 is constantly cooled.

The system 10 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SocBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model. Furthermore, the cooling execution device 500 may receive and store information (traffic information) on a traffic situation from a server that provides traffic information. Note that the information on a traffic situation includes information such as a situation of congestion of vehicles, the number of pedestrians, the presence or absence of an accident, the presence of absence of a construction, and the presence or absence of an event.

Furthermore, the cooling execution device 500 may receive and store weather information from the server that provides the weather information. Note that the weather information includes information such as weather, temperature, humidity, and wind speed. Furthermore, the cooling execution device 500 may receive information on the type of the vehicle 300 from the server 30, and store the information. Note that the information on the type of the vehicle 300 may include information such as the type of the vehicle 300, information on a vehicle type and heat generation of the SoCBox 400, and a parameter for each of vehicle types.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400. Furthermore, the cooling execution device 500 can perform processing similar to prediction processing performed by the management server 100 to be described later.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

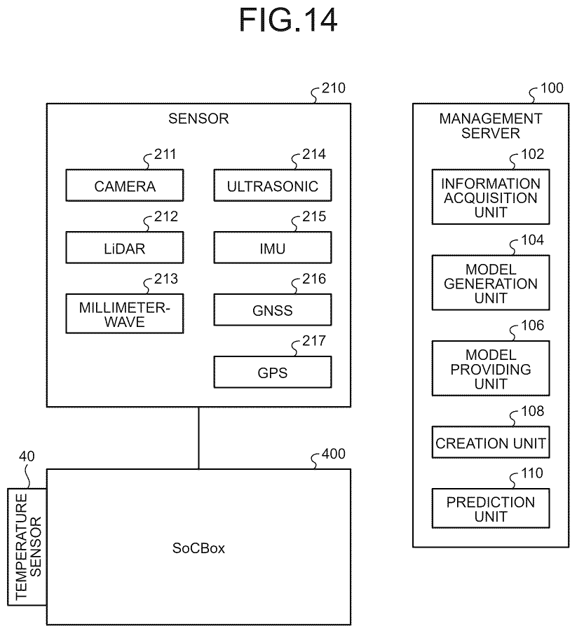

FIG. 14 is an explanatory diagram illustrating a learning phase in the system 10. Here, the sensor 210 mounted on the vehicle 200 is illustrated as including the camera 211, the light detection and ranging (LiDAR) 212, the millimeter-wave sensor 213, the ultrasonic sensor 214, the IMU sensor 215, the global navigation satellite system (GNSS) sensor 216, and a global positioning system (GPS) sensor 217. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes the information acquisition unit 102, the model generation unit 104, the model providing unit 106, a creation unit 108, and a prediction unit 110.

The information acquisition unit 102 acquires various pieces of information. For example, the information acquisition unit 102 acquires the position information on the vehicle 300 including the cooling execution device 500, the temperature information on the SoCBox 400 of the vehicle 300, information on a traffic situation, and weather information. Here, the position information may be acquired from the GNSS sensor or the GPS sensor. Furthermore, the position information may include information on a travel route and a destination of the vehicle 300.

Furthermore, the information acquisition unit 102 acquires, from the cooling execution device 500, the position information on the vehicle 300 including the cooling execution device 500, the temperature information on the SoCBox 400 of the vehicle 300, the information on a traffic situation, and the weather information. Furthermore, for example, the information acquisition unit 102 acquires the weather information from the server that provides weather information. Furthermore, for example, the information acquisition unit 102 acquires the information on a traffic situation from the server that provides traffic information.

Furthermore, the information acquisition unit 102 acquires information on the type of the vehicle 300 from the cooling execution device 500. Furthermore, the information on the type of the vehicle may include information such as the type of the vehicle 300, information on a vehicle type and heat generation of the SoCBox 400, and a parameter for each of vehicle types. Note that the information acquisition unit 102 may acquire various pieces of information at predetermined timing or cycle. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The creation unit 108 creates a map representing the relation between the position of the vehicle 300, the information on a traffic situation, the weather information, and the temperature of the SoCBox 400 from the position information on the vehicle 300 including the cooling execution device 500, the temperature information on the SoCBox 400 of the vehicle 300, the information on a traffic situation, and the weather information, which have been acquired by the information acquisition unit 102. For example, the creation unit 108 creates a map representing the relation between the position of the vehicle 300 and the temperature of the SoCBox 400 for each of the information on a traffic situation and the weather information from the position information on the vehicle 300 including the cooling execution device 500, the temperature information on the SoCBox 400 of the vehicle 300, the information on a traffic situation, and the weather information, which have been acquired by the information acquisition unit 102.

Furthermore, the creation unit 108 creates a map representing the relation between the position of the vehicle 300 and the temperature of the SoCBox 400 for each type of the vehicle 300 from the position information on the vehicle 300 including the cooling execution device 500, the temperature information on the SoCBox 400 of the vehicle 300, and information on the type of the vehicle 300, which have been acquired by the information acquisition unit 102.

The prediction unit 110 predicts the temperature change of the SoCBox 400 based on the position information on the vehicle 300 including the cooling execution device 500, the temperature information on the SoCBox 400 of the vehicle 300, the information on a traffic situation, and the weather information, which have been acquired by the information acquisition unit 102. In the case, the prediction unit 110 may perform prediction by using the position information on the vehicle 300 including the cooling execution device 500, the temperature information on the SoCBox 400 of the vehicle 300, the information on a traffic situation, and the weather information, which have been acquired in the past by the information acquisition unit 102.

For example, the prediction unit 110 predicts the temperature change of the SoCBox 400 based on the position information on the vehicle 300 including the cooling execution device 500, the temperature information on the SoCBox 400 of the vehicle 300, the information on a traffic situation, and the weather information, which have been acquired by the information acquisition unit 102, by using the position information on the vehicle 300 including the cooling execution device 500, the temperature information on the SoCBox 400 of the vehicle 300, the information on a traffic situation, and the weather information, which have been accumulated.

For example, in a case of weather information of rain, the prediction unit 110 predicts the temperature change based on the fact that a heat generation amount increases by approximately 20% from data indicating that the heat generation amount increases by approximately 20% at rainy weather as compared to that at clear weather in information acquired in the past. Furthermore, for example, in a case of a traffic situation of congestion, the prediction unit 110 predicts the temperature change based on the fact that a heat generation amount increases by approximately 30% from data indicating that the heat generation amount increases by approximately 30% at the time of congestion as compared to that at a usual time in information acquired in the past.

Furthermore, the prediction unit 110 predicts the temperature change of the SoCBox 400 based on the position information on the vehicle 300 including the cooling execution device 500, the temperature information on the SoCBox 400 of the vehicle 300, the information on a traffic situation, the weather information, and the map representing the relation between the position of the vehicle 300, the information on a traffic situation, the weather information, and the temperature of the SoCBox 400. The pieces of information have been acquired by the information acquisition unit 102. The map has been created by the creation unit 108.

Furthermore, the prediction unit 110 predicts the temperature change of the SoCBox 400 based on the position information on the vehicle 300 including the cooling execution device 500, the temperature information on the SoCBox 400 of the vehicle 300, the information on a traffic situation, the weather information, and the map representing the relation between the position of the vehicle 300, the information on a traffic situation, the weather information, and the temperature of the SoCBox 400. The pieces of information have been acquired by the information acquisition unit 102. The map has been created by the creation unit 108.

Furthermore, the prediction unit 110 predicts the temperature change of the SoCBox 400 based on the position information on the vehicle 300 including the cooling execution device 500, the temperature information on the SoCBox 400 of the vehicle 300, and the map representing the relation between the position of the vehicle 300 and the temperature of the SoCBox 400 in the type of the vehicle 300. The position information and the temperature information have been acquired by the information acquisition unit 102. The map has been created by the creation unit 108.

The temperature change of the SoCBox 400 predicted by the prediction unit 110 includes a temporal temperature change of the SoCBox 400 of the vehicle 300.

For example, the prediction unit 110 may predict the temporal temperature change of the SoCBox 400 of the vehicle 300 on a travel route from the current position of the vehicle 300 to a destination.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

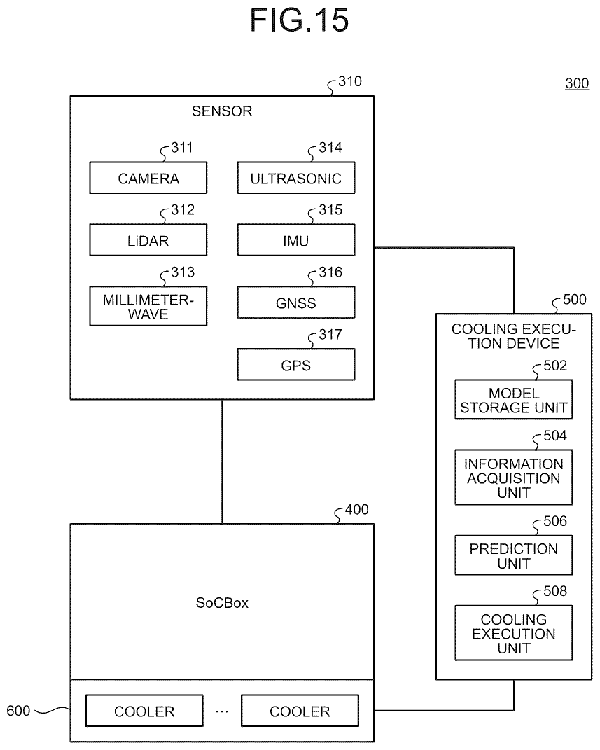

FIG. 15 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, a GNSS sensor 316, and a GPS sensor 317. The vehicle 300 is not required to include all the sensors. The vehicle 300 does not have to include some of the sensors. The vehicle 200 may include a sensor other than the sensors.

The cooling execution device 500 includes a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The information acquisition unit 504 acquires, from the management server 100, a prediction result of the temperature change of the SoCBox 400 predicted by the prediction unit 110 of the management server 100.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502. Furthermore, the prediction unit 506 can perform processing similar to the prediction processing performed by the prediction unit 110 of the management server 100.

The cooling execution unit 508 starts cooling the SoCBox 400 based on the prediction result of the temperature change of the SoCBox 400 acquired by the information acquisition unit 504. For example, the cooling execution unit 508 starts cooling the SoCBox 400 from a predetermined time before the SoCBox 400 starts heat generation by using the prediction result of the temperature change of the SoCBox 400 acquired by the information acquisition unit 504. Furthermore, for example, the cooling execution unit 508 starts cooling the SoCBox 400 from a predetermined time before the timing when the SoCBox 400 is predicted to have a predetermined temperature or more by using the prediction result of the temperature change of the SoCBox 400 acquired by the information acquisition unit 504. Furthermore, for example, the cooling execution unit 508 starts cooling the SoCBox 400 at the timing when a point where the SoCBox 400 is predicted to start heat generation and the current position of the vehicle 300 fall within a predetermined distance by using the prediction result of the temperature change of the SoCBox 400 acquired by the information acquisition unit 504.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 starts cooling the SoCBox 400 by using one or a plurality of coolers selected from a plurality of types of coolers in accordance with the temperature change of the SoCBox 400 by using the prediction result of the temperature change of the SoCBox 400 acquired by the information acquisition unit 504. The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

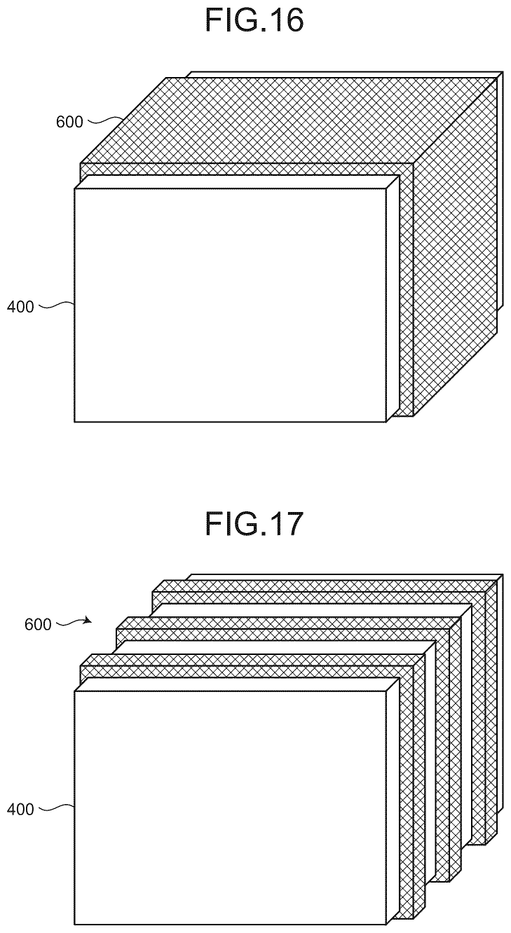

FIG. 16 schematically illustrates an example of the SoCBox 400 and the cooling unit 600. FIG. 16 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 17 schematically illustrates an example of the SoCBox 400 and the cooling unit 600. FIG. 17 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

Furthermore, the cooling execution device 500 of the system 10 starts cooling the SoCBox 400 based on the temperature change of the SoCBox 400 predicted based on the position information on the vehicle 300, the information on the temperature of the SoCBox 400, the information on a traffic situation, and the weather information. The cooling execution device 500 can thereby address the temperature change of the SoCBox 400 in a case where detection amounts of various sensors increase due to an environmental change and a case where the control of automatic driving is complicated, and perform efficient cooling.

Furthermore, the cooling execution device 500 of the system 10 starts cooling the SoCBox 400 based on the temperature change of the SoCBox 400 predicted based on the position information on the vehicle 300, the information on the temperature of the SoCBox 400, the information on a traffic situation, the weather information, and the map representing the relation between the position information on the vehicle 300, the information on a traffic situation, the weather information, and the temperature of the SoCBox 400. The cooling execution device 500 can thereby perform efficient cooling in accordance with the position and a dynamic environment of the vehicle 300.

Furthermore, the cooling execution device 500 of the system 10 creates the map representing the relation between the position information on the vehicle 300 and the temperature of the SoCBox 400 for each of the information on a traffic situation and the weather information, predicts the temperature change of the SoCBox 400, and starts cooling the SoCBox 400. The cooling execution device 500 can thereby perform efficient cooling in accordance with the position of the vehicle 300 for each dynamic environment.

Furthermore, the cooling execution device 500 of the system 10 starts cooling the SoCBox 400 based on the temperature change of the SoCBox 400 predicted based on the position information on the vehicle 300, the information on the temperature of the SoCBox 400, the information on a traffic situation, the weather information, the type of the vehicle 300, and the map representing the relation between the position information on the vehicle 300, the information on a traffic situation, the weather information, and the temperature of the SoCBox 400. The cooling execution device 500 can thereby perform efficient cooling in accordance with the type, position, and dynamic environment of the vehicle 300.

Furthermore, the cooling execution device 500 of the system 10 starts cooling the SoCBox 400 from a predetermined time before the SoCBox 400 starts heat generation based on the prediction result of the temperature change of the SoCBox 400. The cooling execution device 500 can thereby reduce the possibility of overheating, and perform efficient cooling.

Furthermore, the cooling execution device 500 of the system 10 performs cooling with a plurality of coolers in accordance with the temperature change of the SoCBox 400 by using the prediction result of the temperature change of the SoCBox 400. The cooling execution device 500 can thereby perform efficient cooling suitable for the temperature change.

Furthermore, the cooling execution device 500 of the system 10 performs cooling with a water cooler and a liquid nitrogen cooler in accordance with the temperature change of the SoCBox 400 by using the prediction result of the temperature change of the SoCBox 400. The cooling execution device 500 can thereby perform efficient cooling by using a cooler suitable for the temperature change.

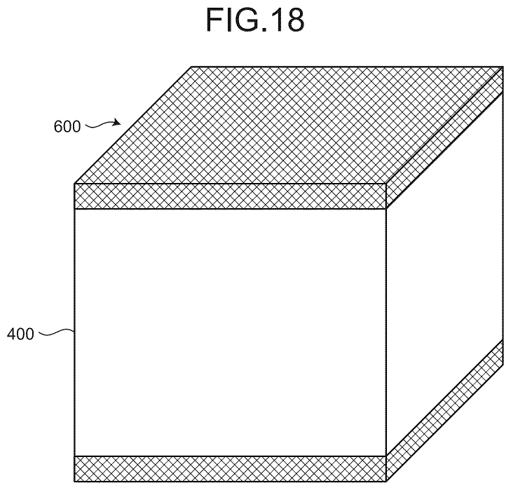

FIG. 18 schematically illustrates an example of the SoCBox 400 and the cooling unit 600. FIG. 18 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Fourth Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox including a plurality of SoCs by utilizing artificial intelligence (AI).

Advanced arithmetic in a vehicle is difficult since a SoCBox easily has high temperature (problem for fully automatic driving). For example, a change in a driving situation may increase detection amounts of various sensors and complicate the control of automatic driving, which may overheat the SoCBox. A SoCBox including a plurality of SoCs (integrated circuits) does not uniformly generate heat. For example, when certain control of automatic driving is performed, only a SoC responsible for the control of automatic driving generates heat. In such a case, AI predicts heat dissipation of the SoCBox and the position thereof and cools the position where heat is dissipated simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

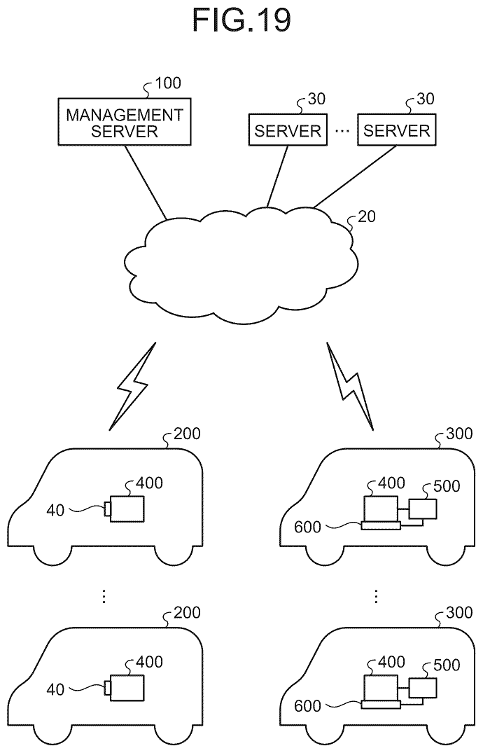

FIG. 19 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 is a control device that includes a plurality of SoCs and that controls automatic driving of the vehicle by using sensor values of a plurality of sensors mounted on the vehicle. An extremely high processing load is put in the control of automatic driving of the vehicle, which may cause the SoCBox 400 to have extremely high temperature.

An excessively high temperature of the SoCBox 400 may discourage the normal operation of the SoCBox 400, and impose a negative effect on the vehicle.

The system 10 according to the embodiment predicts a temperature change at each position of the SoCBox 400 based on position information on a Soc of the SoCBox 400, information on processing of the SoC, and information on the driving situation of the vehicle. The system 10 starts cooling the SoCBox 400 based on the temperature change at each position. For example, the system 10 predicts heat generation occurred for each of various pieces of control processing, such as straight traveling, right and left turning, stopping, and situation determination using various sensors, and the position thereof, and immediately starts cooling the SoCBox 400. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The system 10 may predict the temperature change at each position of the SoCBox 400 by AI. The temperature change at each position of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature at each position of the SoCBox 400. The SoCBox 400 controls automatic driving of the vehicle 200 by using sensor values of a plurality of sensors mounted on the vehicle 200 and external information received from a plurality of types of servers 30. Furthermore, the SoCBox 400 stores position information on a SoC of the SoCBox 400, information on processing of each SoC, and information on the driving situation of the vehicle 300. Here, the information on processing of each SoC refers to information on processing and control performed by each SoC. The information includes information on processing such as acceleration, deceleration, right and left turning, stopping, traveling vehicle detection, pedestrian detection, obstacle detection, and detection and various pieces of arithmetic performed by various sensors, which are controlled by each SoC. Furthermore, the information on the driving situation of the vehicle 300 refers to information on the driving situation and the operation situation of the vehicle 300.

The information includes information on processing such as acceleration, deceleration, right and left turning, stopping, traveling vehicle detection, pedestrian detection, obstacle detection, and detection and various pieces of arithmetic performed by various sensors. Note that the above-described processing contents and driving situations are examples. Processing and a driving situation other than those described are included. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change at each position of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change at each position of the SoCBox 400 at the time when the SoCBox 400 has acquired these pieces of information. The management server 100 thereby generates a learning model in which the information acquired by the SoCBox 400 is used as input and the temperature change at each position of the SocBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

Furthermore, the cooling execution device 500 may store the position information on each SoC of the SoCBox 400 acquired from the SoCBox 400, the information on processing of each SoC, and the information on the driving situation of the vehicle 300.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change at each position of the SoCBox 400. Furthermore, the cooling execution device 500 can perform processing similar to prediction processing performed by the management server 100 to be described later.

When predicting that the SoCBox 400 is starting heat generation or predicting that the SoCBox 400 has a temperature at each position higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

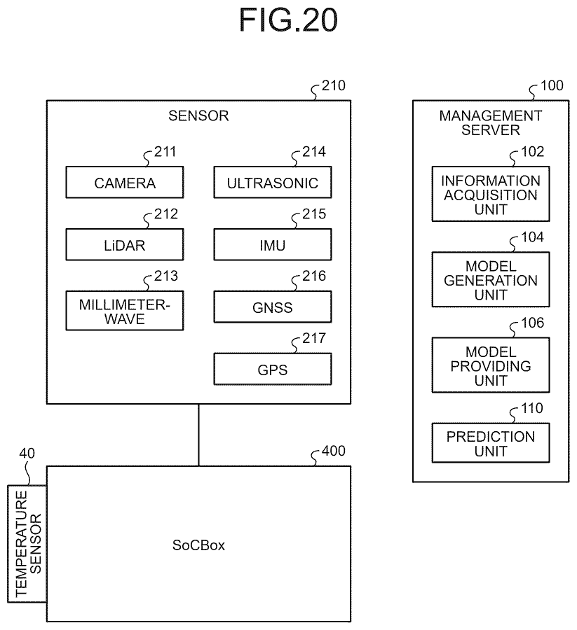

FIG. 20 is an explanatory diagram illustrating a learning phase in the system 10. Here, the sensor 210 mounted on the vehicle 200 is illustrated as including the camera 211, the light detection and ranging (LiDAR) 212, the millimeter-wave sensor 213, the ultrasonic sensor 214, the IMU sensor 215, the global navigation satellite system (GNSS) sensor 216, and a global positioning system (GPS) sensor 217. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information. Furthermore, the SoCBox 400 stores position information on each SoC held by the SoCBox 400.

The temperature sensor 40 measures a temperature change at each position of the SoCBox 400. The SoCBox 400 transmits, to the management server 100, the sensor information received from the sensor 210, the external information received from the servers 30, and the temperature change at each position measured by the temperature sensor 40 at the time when these pieces of information have been acquired and the automatic driving has been controlled.

The management server 100 includes the information acquisition unit 102, the model generation unit 104, the model providing unit 106, and a prediction unit 110.

The information acquisition unit 102 acquires various pieces of information. For example, the information acquisition unit 102 acquires the position information on each SoC of the SoCBox 400, the information on processing of each SoC, and the information on the driving situation of the vehicle 300. For example, the information acquisition unit 102 acquires, from the cooling execution device 500, the position information on each SoC of the SoCBox 400, the information on processing of each SoC, and the information on the driving situation of the vehicle 300. For example, the information acquisition unit 102 may acquire the position information on each So by identifying the position of each SoC using information such as a manufacturer and a model number of the SoCBox 400.

Note that the information acquisition unit 102 may acquire various pieces of information at predetermined timing or cycle. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change at each position of the SoCBox 400 at the time when the SoCBox 400 has acquired the information. The model generation unit 104 thereby generates the learning model in which the information acquired by the SoCBox 400 is used as input and the temperature change at each position of the SoCBox 400 is used as output.

The model providing unit 106 provides the learning model generated by the model generation unit 104. The model providing unit 106 may transmit the learning model to the cooling execution device 500 mounted on the vehicle 300.

The prediction unit 110 predicts the temperature change at each position of the SoCBox 400 based on the position information on each SoC of the SoCBox 400, the information on processing of each SoC, and the information on the driving situation of the vehicle 300, which have been acquired by the information acquisition unit 102. For example, the prediction unit 110 predicts the temperature change at each position of the SoCBox 400 by using information that traveling is performed while obstacle detection and pedestrian detection are performed as information on the driving situation, information on a SoC that controls the obstacle detection, the pedestrian detection, and traveling as information on processing of each SoC, and the position information on the Soc of the SoCBox 400. These pieces of information have been acquired by the information acquisition unit 102.

Furthermore, the prediction unit 110 predicts the temporal temperature change at each position of the SoCBox 400 by using the position information on each SoC of the SoCBox 400, the information on processing of each Soc, and the information on the driving situation of the vehicle 300, which have been acquired by the information acquisition unit 102.

For example, the prediction unit 110 predicts the temperature change at each position of the SoCBox 400 in a case where a driving situation continues by using information that traveling is performed while obstacle detection and pedestrian detection are performed as information on the driving situation, information on a SoC that controls the obstacle detection, the pedestrian detection, and traveling as information on processing of each SoC, and the position information on the Soc of the SoCBox 400. These pieces of information have been acquired by the information acquisition unit 102.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

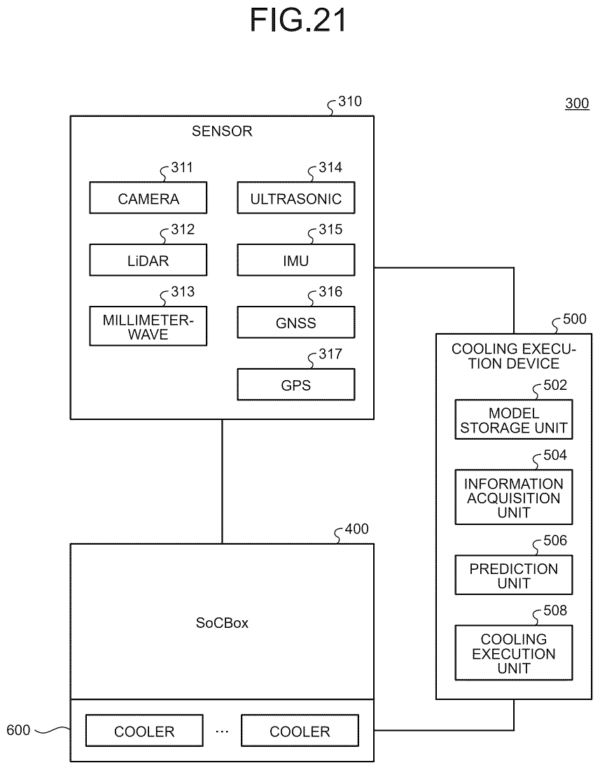

FIG. 21 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, a GNSS sensor 316, and a GPS sensor 317. The vehicle 300 is not required to include all the sensors. The vehicle 300 does not have to include some of the sensors. The vehicle 200 may include a sensor other than the sensors.

The cooling execution device 500 includes a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500. Furthermore, for example, the information acquisition unit 504 acquires information on the position of each SoC of the SoCBox 400 from the SoCBox 400.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The information acquisition unit 504 acquires, from the management server 100, a prediction result of the temperature change at each position of the SoCBox 400 predicted by the prediction unit 110 of the management server 100.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502. Furthermore, the prediction unit 506 can perform processing similar to the prediction processing performed by the prediction unit 110 of the management server 100.

The cooling execution unit 508 starts cooling the SoCBox 400 based on the prediction result of the temperature change at each position of the SoCBox 400 acquired by the information acquisition unit 504. For example, the cooling execution unit 508 starts cooling the position where the SoCBox 400 is generating heat by using the prediction result of the temperature change at each position of the SoCBox 400 acquired by the information acquisition unit 504.

Furthermore, for example, the cooling execution unit 508 starts cooling the position where the SoCBox 400 is generating heat from a predetermined time before the SoCBox 400 starts heat generation by using the prediction result of the temperature change at each position of the SoCBox 400 acquired by the information acquisition unit 504.

Furthermore, for example, the cooling execution unit 508 starts cooling the position where the SoCBox 400 is generating heat from a predetermined time before the timing when the SoCBox 400 is predicted to have a predetermined temperature or more at each position by using the prediction result of the temperature change at each position of the SoCBox 400 acquired by the information acquisition unit 504.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 starts cooling the position where the SoCBox 400 is generating heat by using one or a plurality of coolers selected from a plurality of types of coolers in accordance with the temperature change at each position of the SoCBox 400 by using the prediction result of the temperature change at each position of the SoCBox 400 acquired by the information acquisition unit 504. The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the position where the SoCBox 400 is generating heat with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the position where the SoCBox 400 is generating heat by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the position where the SoCBox 400 is generating heat by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

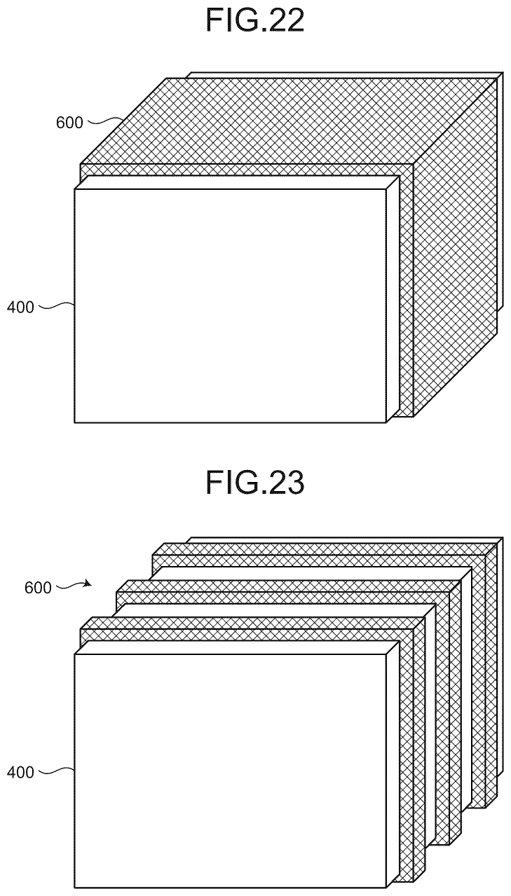

FIG. 22 schematically illustrates an example of the SoCBox 400 and the cooling unit 600. FIG. 22 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 23 schematically illustrates an example of the SoCBox 400 and the cooling unit 600. FIG. 23 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

The cooling execution device 500 of the system 10 starts cooling the position where the SoCBox 400 is generating heat based on the prediction result of the temperature change at each position of the SoCBox 400 predicted from the position information of a Soc in the SoCBox 400, the information on the control of the SoC, and the driving situation of the vehicle 300. The cooling execution device 500 can thereby cool only a location that needs cooling, and perform efficient cooling.

Furthermore, the cooling execution device 500 of the system 10 starts cooling the position where the SoCBox 400 is generating heat by using the prediction result of the temporal temperature change at each position of the SoCBox 400 predicted from the position information of a Soc in the SoCBox 400, the information on the control of the SoC, and the driving situation of the vehicle 300. The cooling execution device 500 can thereby cool only a location that needs cooling at effective timing, and perform efficient cooling.

Furthermore, the cooling execution device 500 of the system 10 starts cooling the position where the SoCBox 400 is generating heat before heat is generated by using the prediction result of the temperature change at each position of the SoCBox 400 predicted from the position information of a Soc in the SoCBox 400, the information on the control of the Soc, and the driving situation of the vehicle 300. The cooling execution device 500 can thereby cool only a location that needs cooling while preventing overheating. The cooling execution device 500 can perform efficient cooling.

Furthermore, the cooling execution device 500 of the system 10 performs cooling with a plurality of coolers in accordance with the temperature change at each position of the SoCBox 400 by using the prediction result of the temperature change at position of the SoCBox 400. The cooling execution device 500 can thereby perform efficient cooling suitable for the temperature change.

Furthermore, the cooling execution device 500 of the system 10 performs cooling with a water cooler and a liquid nitrogen cooler in accordance with the temperature change at each position of the SoCBox 400 by using the prediction result of the temperature change at each position of the SoCBox 400. The cooling execution device 500 can thereby perform efficient cooling by using a cooler suitable for the temperature change.

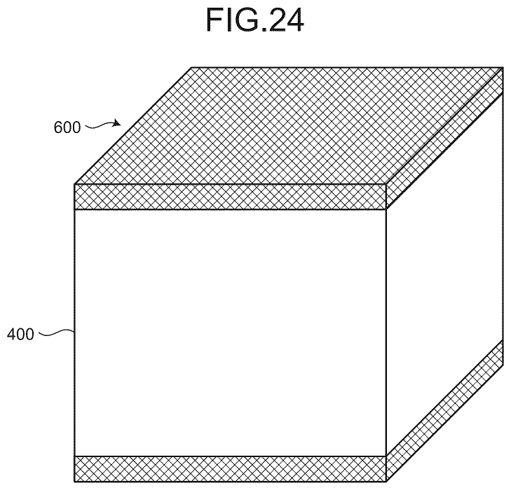

FIG. 24 schematically illustrates an example of the SoCBox 400 and the cooling unit 600. FIG. 24 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Fifth Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

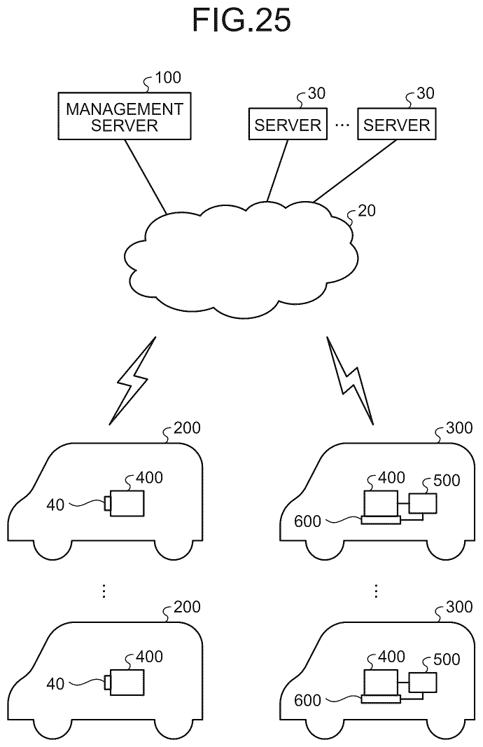

FIG. 25 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 controls automatic driving of the vehicle by using sensor values of a plurality of sensors mounted on the vehicle. An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The cooling execution device 500 according to the embodiment predicts a temperature change of the SoCBox 400, and starts cooling the SoCBox 400 based on the temperature change. For example, when predicting that the SoCBox 400 is starting heat generation, the cooling execution device 500 immediately starts cooling the SoCBox 400 accordingly. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The cooling execution device 500 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

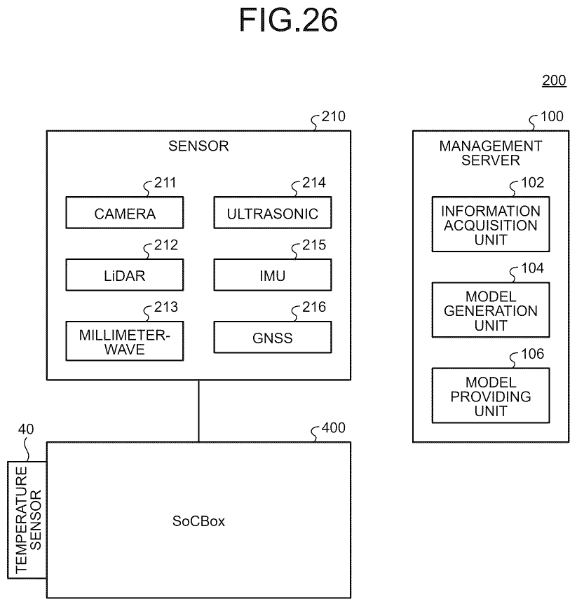

FIG. 26 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SocBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

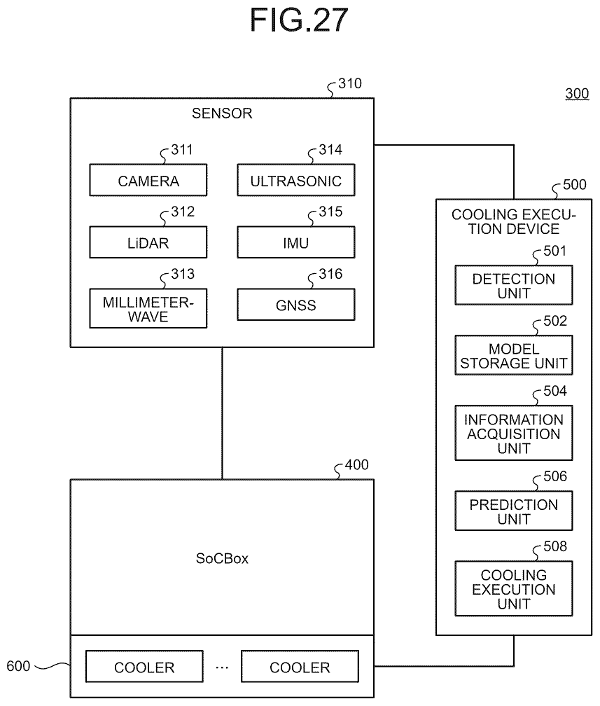

FIG. 27 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling execution device 500 includes a detection unit 501, a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The detection unit 501 detects a temperature of the control device (SoCBox 400) that controls the automatic driving of the vehicle and that is mounted on the vehicle. Furthermore, the detection unit 501 may detect the temperature of each of a plurality of portions of the SoCBox 400. For example, the detection unit 501 can detect the temperatures of one or a plurality of SoCBoxes 400, the occurrence of an increase or decrease in temperature, and a numerical value of a changing temperature.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The prediction unit 506 predicts a temperature change of the control device (SoCBox 400) that controls the automatic driving of the vehicle and that is mounted on the vehicle. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502. Moreover, the prediction unit 506 may predict a temperature change of each of a plurality of portions of the control device (SoCBox 400). For example, the prediction unit 506 can predict the occurrence of an increase or decrease in temperature of one or a plurality of SoCBoxes 400, and predict a numerical value of a changing temperature.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 cools the control device (SoCBox 400) by using a predetermined cooler based on a time when the temperature detected by the detection unit 501 continues to be a predetermined temperature or more. Specifically, when the time when a predetermined temperature or more continues exceeds a predetermined threshold, the cooling execution unit 508 can execute cooling by using a cooler including a plurality of one or a plurality of types of air coolers, one or a plurality of types of water coolers, and a liquid nitrogen cooler. For example, when the time when the temperature detected by the detection unit 501 continues to be a predetermined temperature or more continues beyond a predetermined threshold (e.g., time of predetermined temperature or more continues for 10 minutes or more), the cooling execution unit 508 may cool the control device by using a predetermined cooler (e.g., air cooler, water cooler, and liquid nitrogen cooler). Note that the predetermined threshold (time) regarding the time when the above-described predetermined temperature or more continues is a condition that can be optionally set, and is not limited.

Furthermore, the cooling execution unit 508 may execute rapid cooling when a temperature exceeds a predetermined threshold. For example, when a temperature at which overheating occurs is exceeded, the cooling execution unit 508 may execute the rapid cooling. The temperature is used as the predetermined threshold. Note that any threshold condition may be set as the predetermined threshold here.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The cooling execution unit 508 performs cooling by using the above-described cooler based on a time when a predetermined temperature or more continues as the temperature change predicted by the prediction unit 506. For example, when traveling is performed through a travel point where a predetermined temperature or more is predicted to continue beyond a predetermined time as a temperature change, the cooling execution unit 508 can execute cooling by using the above-described coolers.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

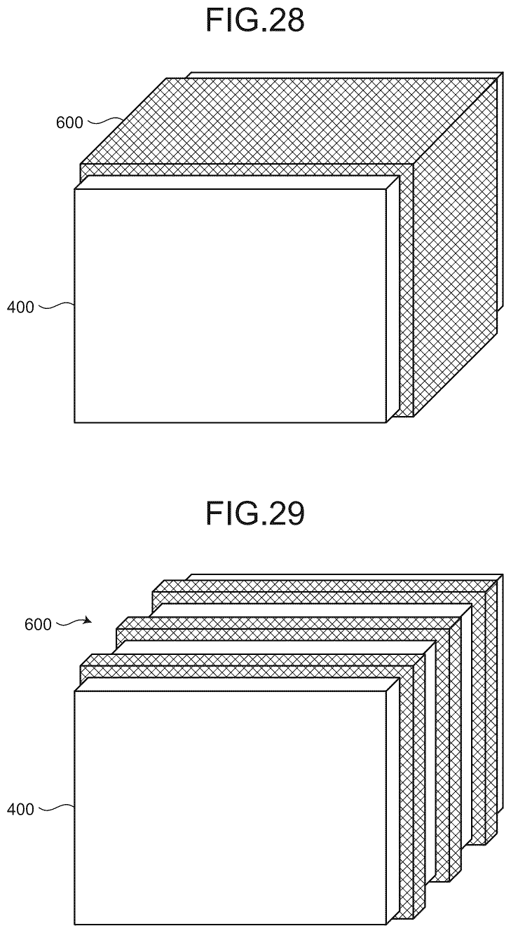

FIG. 28 schematically illustrates an example of the SoCBox 400 and the cooling unit 600. FIG. 28 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 29 schematically illustrates an example of the SoCBox 400 and the cooling unit 600. FIG. 29 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

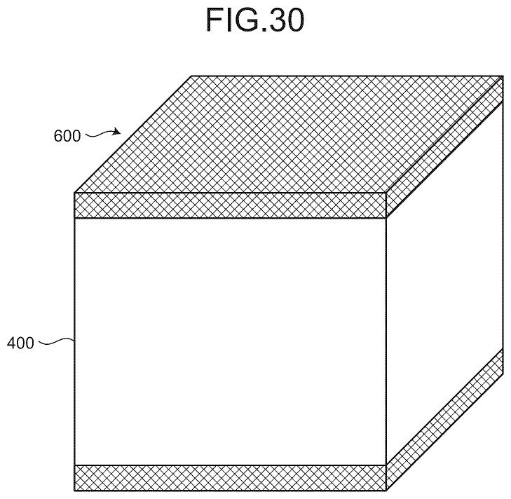

FIG. 30 schematically illustrates an example of the SoCBox 400 and the cooling unit 600. FIG. 30 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Sixth Embodiment

A problem of heat generation arises when a system on chip (Soc) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

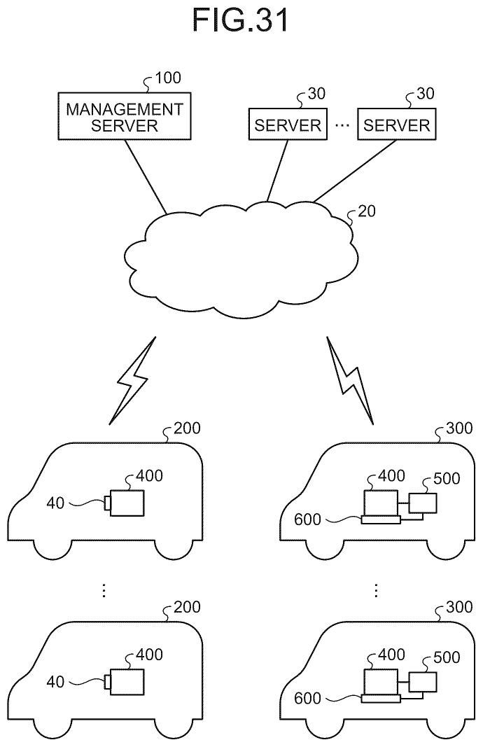

FIG. 31 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 controls automatic driving of the vehicle by using sensor values of a plurality of sensors mounted on the vehicle. An extremely high processing load is put in the control of automatic driving of the vehicle, which may cause the SoCBox 400 to have extremely high temperature.

An excessively high temperature of the SoCBox 400 may discourage the normal operation of the SoCBox 400, and impose a negative effect on the vehicle.

The cooling execution device 500 according to the embodiment predicts a temperature change of the SoCBox 400, and starts cooling the SoCBox 400 based on the temperature change. For example, when predicting that the SoCBox 400 is starting heat generation, the cooling execution device 500 immediately starts cooling the SoCBox 400 accordingly. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The cooling execution device 500 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

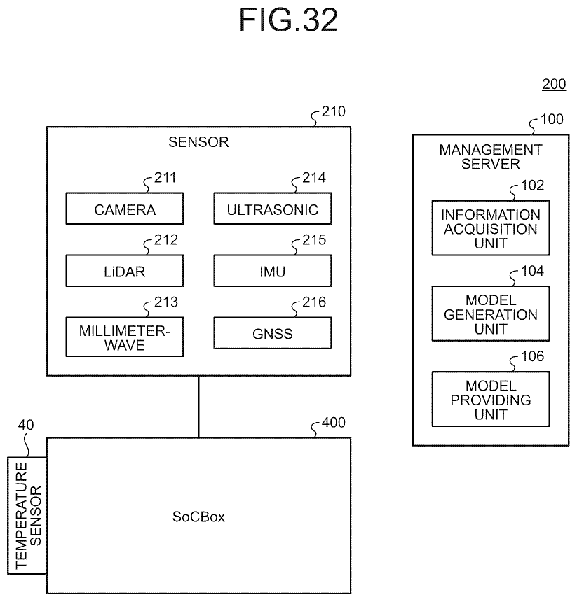

FIG. 32 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

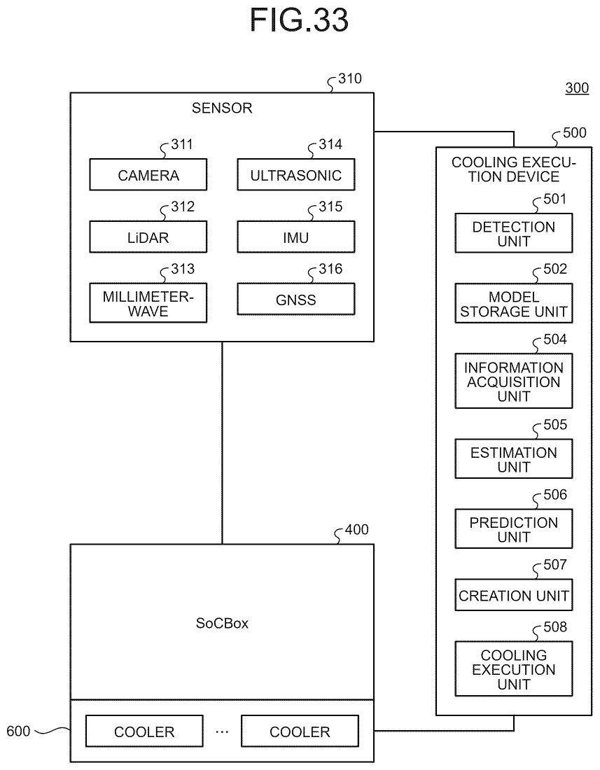

FIG. 33 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling execution device 500 includes a detection unit 501, a model storage unit 502, an information acquisition unit 504, an estimation unit 505, a prediction unit 506, a creation unit 507, and a cooling execution unit 508. The model storage unit 502 stores the learning model received from the management server 100.

The information acquisition unit 504 acquires information acquired by the SoCBox 400.

The detection unit 501 detects a temperature change of the control device (SoCBox 400) that controls the automatic driving of the vehicle and that is mounted on the vehicle. Furthermore, the detection unit 501 may detect the temperature change of each of a plurality of portions of the SoCBox 400. For example, the detection unit 501 can detect the occurrence of an increase or decrease in temperature of one or a plurality of SoCBoxes 400, and detect a numerical value of a changing temperature.

The estimation unit 505 estimates switching between automatic driving and manual driving based on a preset travel route. Moreover, the estimation unit 505 may estimate whether or not switching from automatic driving to manual driving occurs based on the road condition of the travel route. For example, the estimation unit 505 can estimate whether or not the switching from automatic driving to manual driving occurs based on road conditions, such as many people, the occurrence of congestion, the occurrence of an accident, the occurrence of a construction or the like, and the occurrence of road closure, in a preset travel route.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The prediction unit 506 predicts a temperature change of the control device (SoCBox 400) that controls the automatic driving of the vehicle and that is mounted on the vehicle. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502.

The creation unit 507 creates a cooling schedule in which a predetermined cooler is set based on an estimation result of the estimation unit 505. Specifically, when the estimation unit 505 estimates that automatic driving is switched to manual driving, the creation unit 507 may create a cooling schedule in which a cooler is set for a travel section of the manual driving, which is assumed to have a heat generation amount larger than that of the manual driving. In contrast, when the estimation unit 505 estimates that manual driving is switched to automatic driving, the creation unit 507 may create a cooling schedule in which a cooler is set for a travel section of the automatic driving, which is assumed to have a heat generation amount smaller than that of the automatic driving.

For example, when the estimation unit 505 estimates that the switching from the automatic driving to the manual driving occurs due to a change in a road condition (e.g., occurrence of situation in which automatic traveling is difficult) on the travel route preset by the estimation unit 505, the creation unit 507 may create a cooling schedule in which a cooler suitable for the manual driving is set. In contrast, when the estimation unit 505 estimates that the switching from the manual driving to the automatic driving occurs due to a change in a road condition (e.g., situation in which automatic traveling is possible) on the travel route preset by the estimation unit 505, the creation unit 507 may create a cooling schedule in which a cooler suitable for the automatic driving is set.

The creation unit 507 may compare an actual temperature change of the control device (SoCBox 400) detected by the detection unit 501 with a predicted temperature change predicted by the prediction unit 506. When the predicted temperature change exceeds the actual temperature change, the creation unit 507 may create a cooling schedule in which a predetermined cooler is set. For example, the creation unit 507 may perform cooling by using a predetermined cooler based on a prediction made by the prediction unit 506 that the temperature change of the control device (SoCBox 400) is a temperature increase of 5° C. and a detection result, from the detection unit 501, indicating that the actual temperature change is a temperature increase of 10° C.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 cools the control device (SoCBox 400) based on the cooling schedule created by the creation unit 507. The control device (SoCBox 400) controls the automatic driving of the vehicle, and is mounted on the vehicle. For example, when the creation unit 507 creates a cooling schedule for the travel section of the manual driving or a cooling schedule for the travel section of the automatic driving, the cooling execution unit 508 may cool the control device (SoCBox 400) with a cooler, for a cooling time, and at cooling timing, which have been set in the cooling schedule.

Furthermore, when the creation unit 507 creates a cooling schedule based on the comparison between the predicted temperature change and the actual temperature change, the cooling execution unit 508 may cool the control device (SoCBox 400) with a cooler, for a cooling time, and at cooling timing, which have been set in the cooling schedule.

The cooling execution unit 508 may cool the control device (SoCBox 400) by using a cooler selected from a plurality of coolers each of which cools each of a plurality of portions of the control device (SoCBox 400) based on the cooling schedule created by the creation unit 507. For example, when an air cooler, a water cooler, and a liquid nitrogen cooler are set in the cooling schedule created by the creation unit 507 and a condition is further set for cooling the plurality of portions of the control device, the cooling execution unit 508 may select one or a plurality of the above-described plurality of coolers to execute cooling.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

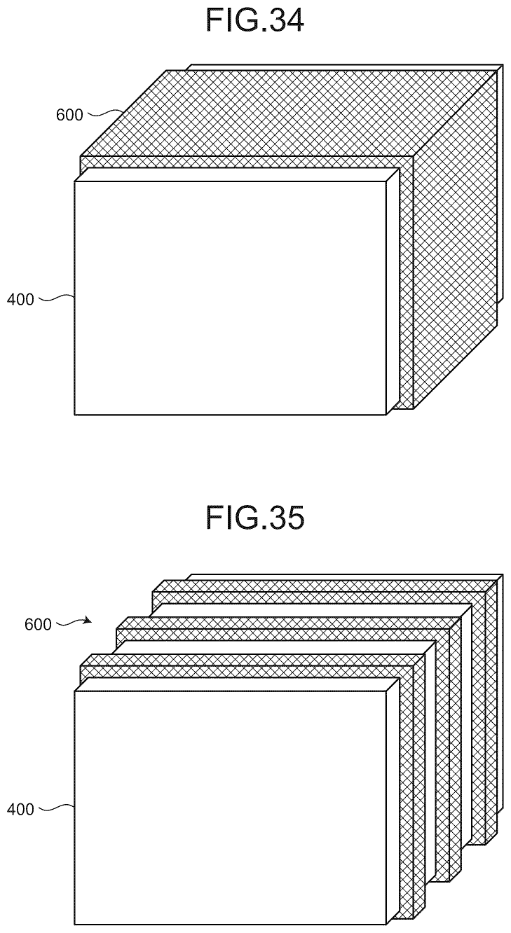

FIG. 34 schematically illustrates an example of the SoCBox 400 and the cooling unit 600. FIG. 34 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 35 schematically illustrates an example of the SoCBox 400 and the cooling unit 600. FIG. 35 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

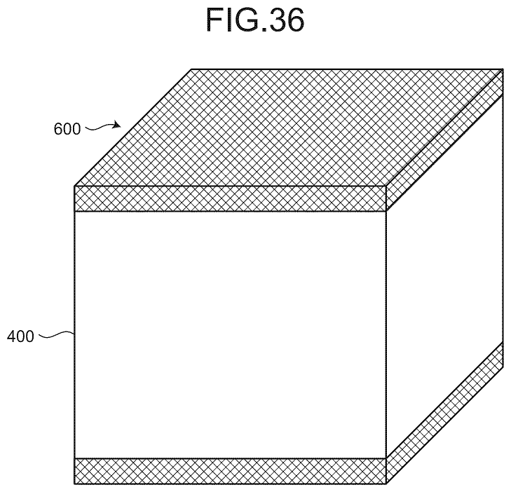

FIG. 36 schematically illustrates an example of the SoCBox 400 and the cooling unit 600. FIG. 36 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Seventh Embodiment

A problem of heat generation arises when a system on chip (SoC) (processing chip) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). For example, the SoCBox includes a plurality of SoCs. As the control of the automatic driving is complicated, processing performed by the SoCs increases. Accordingly, the SoCBox may have a high temperature to cause overheating. Therefore, AI predicts heat dissipation of the SoCBox, and performs cooling so that the temperature of the SoCBox is held within a predetermined temperature range. The SoCBox is thereby prevented from having high temperature. This enables the advanced arithmetic in the vehicle. This is expected to be applicable to cooling not only a SoCBox but a battery, and may be a solution to high temperature caused by rapid charging.

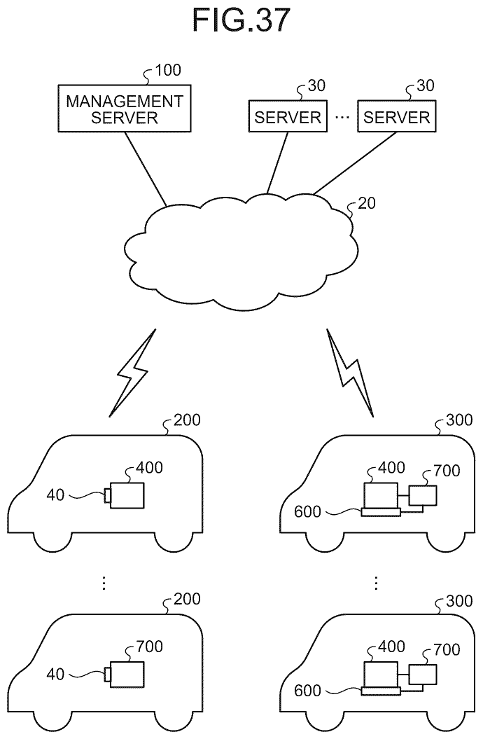

FIG. 37 schematically illustrates an example of a system 10. The system 10 includes a management server 100. The system 10 includes a SoCBox 400. The system 10 includes a cooling device 700. The system 10 includes a cooling unit 600.

The SoCBox 400, the cooling device 700, and the cooling unit 600 are mounted on a vehicle. The SoCBox 400 is a control device including a plurality of SoCs, and controls automatic driving of the vehicle by using sensor values of a plurality of sensors mounted on the vehicle.

An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The cooling device 700 according to the embodiment predicts a temperature change of the SoCBox 400, and cools the SoCBox 400 so that the temperature of the SoCBox 400 is held within a predetermined temperature range based on the temperature change. For example, when the SoCBox 400 is predicted to start heat generation and a predicted temperature after the heat generation exceeds a predetermined temperature range, the cooling device 700 cools the SoCBox 400, and holds the temperature within the predetermined temperature range.

This enables the cooling device 700 to hold the temperature of the SoCBox 400 within the predetermined temperature range, and reduces a case where the SoCBox 400 is rapidly cooled. As a result, the total energy consumed for cooling can be reduced.

The cooling device 700 may determine the predetermined temperature range in accordance with a threshold temperature preliminarily determined for the SoCBox 400. For example, the cooling device 700 determines, as the predetermined temperature range, a temperature range around any temperature approximately 5° C. lower than a threshold temperature preset in consideration of normal pieces of processing to be performed by various SoCs of the SoCBox 400.

The cooling device 700 constantly cools the SoCBox 400 so that a predicted temperature after heat generation is held within any temperature range approximately 5° C. lower than a threshold temperature instead of starting rapid cooling several times after the predicted temperature reaches around the threshold temperature. This can reduce the total energy used for cooling.

Here, the predetermined temperature range is a temperature range centered on any temperature lower than the threshold temperature set as an upper limit temperature at which the plurality of SoCs of the SoCBox can normally perform processing. No limitation is put on the temperature of the difference between the threshold temperature and the center temperature within the temperature range and the width of the temperature range.

The cooling device 700 may predict the temperature change of the SoCBox 400 by AI. Note that the temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30.

The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling device 700, and the cooling unit 600 are mounted on the vehicle 300.

The cooling device 700 may receive the learning model generated by the management server 100 from the management server 100, and store the learning model.

The cooling device 700 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling device 700 inputs the acquired information to the learning model. The cooling device 700 thereby predicts the temperature change of the SoCBox 400.

When the SoCBox 400 is predicted to start heat generation and a predicted temperature after the heat generation exceeds a predetermined temperature range, the cooling device 700 starts cooling the SoCBox 400 with the cooling unit 600, and holds the temperature of the SoCBox 400 within the predetermined temperature range.

The SoCBox 400, the cooling device 700, the management server 100, and the servers 30 may communicate via a network 20. The network 20 may include a vehicle network. The network 20 may include the Internet. The network 20 may include a local area network (LAN).

The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

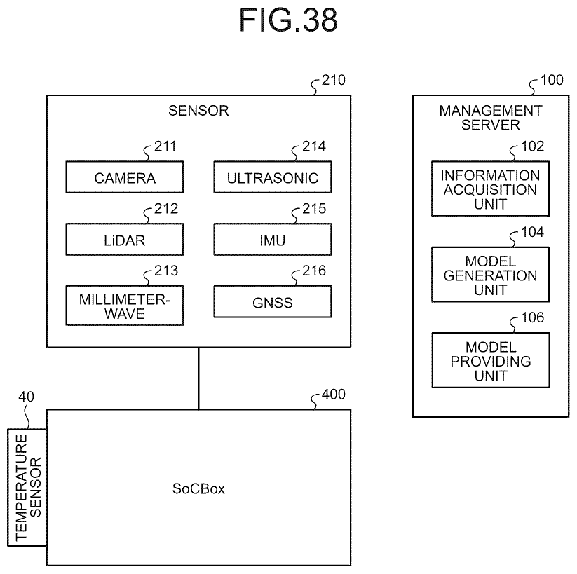

FIG. 38 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling device 700 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled.

The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

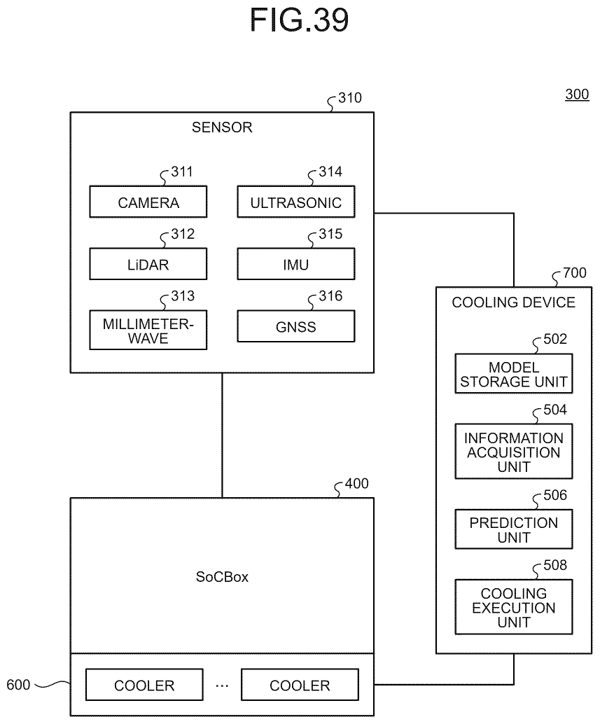

FIG. 39 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling device 700 includes a model storage unit 502, an information acquisition unit 504, a prediction unit 506, and a cooling execution unit 508. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310.

The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling device 700.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling device 700.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502.

The cooling execution unit 508 performs cooling so that the temperature of the SoCBox 400 is held within the predetermined temperature range based on the temperature change of the SoCBox 400 predicted by the prediction unit 506. For example, when the prediction unit 506 predicts that the SoCBox 400 has a temperature higher than the upper limit temperature within the predetermined temperature range, the cooling execution unit 508 starts cooling the SoCBox 400, and holds the temperature of the SoCBox 400 within the predetermined temperature range.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers.

In a specific example, when predicting that the SoCBox 400 has a temperature exceeding the upper limit temperature within the predetermined temperature range, the cooling execution unit 508 starts cooling using one of the plurality of coolers. When predicting that the SoCBox 400 has an increasing temperature exceeding the above-described upper limit temperature, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the above-described upper limit temperature, the cooling execution unit 508 starts cooling using an air cooler.

When the temperature of the SoCBox 400 is predicted to still increase and exceed the above-described upper limit temperature, the cooling execution unit 508 starts cooling using a water cooler. When the temperature of the SoCBox 400 is predicted to still yet increase and exceed the above-described upper limit temperature, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

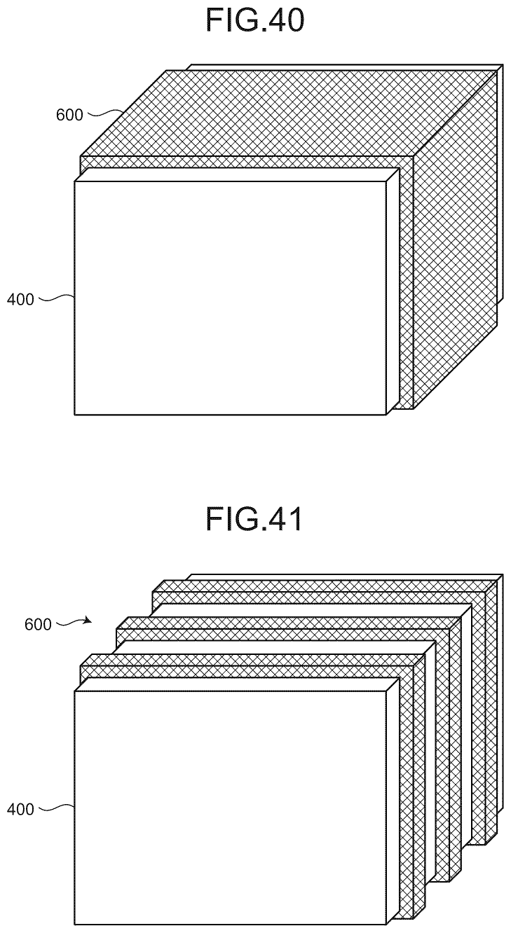

FIG. 40 schematically illustrates an example of the SoCBox 400 and the cooling unit 600. FIG. 40 illustrates a case where the cooling unit 600 includes one cooler. When predicting that the SoCBox 400 is starting heat generation or predicting that the SoCBox 400 has a temperature exceeding a temperature within the predetermined temperature range, the cooling device 700 starts cooling with the cooling unit 600. The cooling device 700 can thereby cool the entire SoCBox 400.

FIG. 41 schematically illustrates an example of the SoCBox 400 and the cooling unit 600. FIG. 41 illustrates a case where the cooling unit 600 includes a plurality of coolers each of which cools each of a plurality of portions of the SoCBox 400.

When predicting that one of a plurality of portions of the SoCBox 400 is starting heat generation or predicting that one of the plurality of portions has a temperature exceeding a predetermined temperature range on the prediction of a temperature change of each of the plurality of portions, the cooling device 700 executes cooling using only a cooler suitable for the portion. The cooling device 700 can thereby perform efficient cooling.

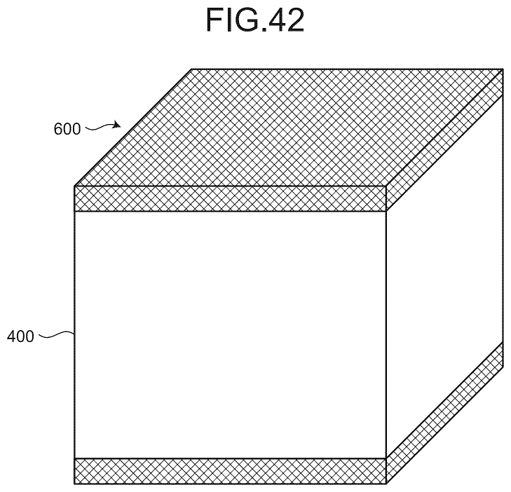

FIG. 42 schematically illustrates an example of the SoCBox 400 and the cooling unit 600. FIG. 42 illustrates a case where the cooling unit 600 includes two types of coolers. When predicting that one of a plurality of portions of the SoCBox 400 is starting heat generation or predicting that one of the plurality of portions has a temperature exceeding a predetermined temperature range on the prediction of a temperature change of each of the plurality of portions, the cooling device 700 executes cooling using only a cooler suitable for the portion. The cooling device 700 can thereby perform efficient cooling.

Furthermore, as the SoCBox 400 has an increasing temperature, the cooling device 700 increases the number of coolers to be used. That is, in the example, first, cooling using one of the two types of coolers is started. When the SoCBox 400 has a still increasing temperature, cooling using the other cooler is started. Energy to be used for cooling can thereby be made more efficient.

### Eighth Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). AI predicts heat dissipation of the SoCBox and performs cooling simultaneously with the heat dissipation to prevent the SoCBox from having high temperature. This enables the advanced arithmetic in the vehicle. This is expected to be applicable to cooling not only a SoCBox but a battery, and may be a solution to high temperature caused by rapid charging.

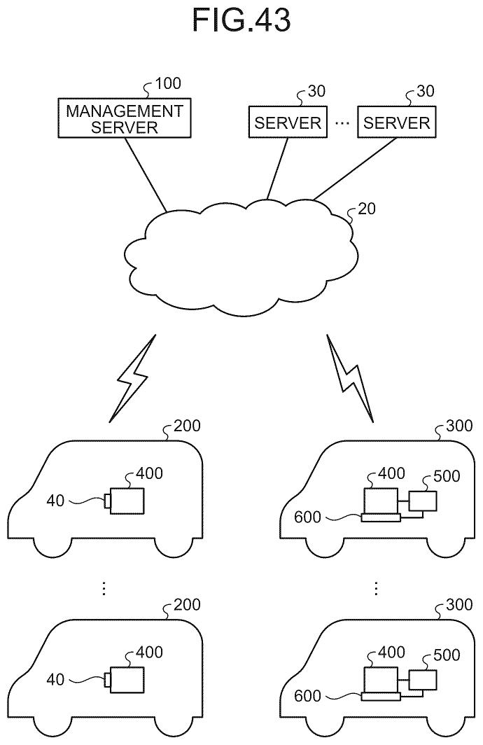

FIG. 43 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 controls automatic driving of the vehicle by using sensor values of a plurality of sensors mounted on the vehicle. An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The cooling execution device 500 according to the embodiment predicts a temperature change of the SoCBox 400, and starts cooling the SoCBox 400 based on the temperature change. For example, when predicting that the SoCBox 400 is starting heat generation, the cooling execution device 500 immediately starts cooling the SoCBox 400 accordingly. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The cooling execution device 500 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

The cooling execution device 500 acquires, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 inputs the acquired information to the learning model. The cooling execution device 500 thereby predicts the temperature change of the SoCBox 400.

When predicting that the SoCBox 400 is starting heat generation or predicting that the SoCBox 400 has a temperature higher than a predetermined threshold, the cooling execution device 500 starts cooling the SoCBox 400 with the cooling unit 600.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

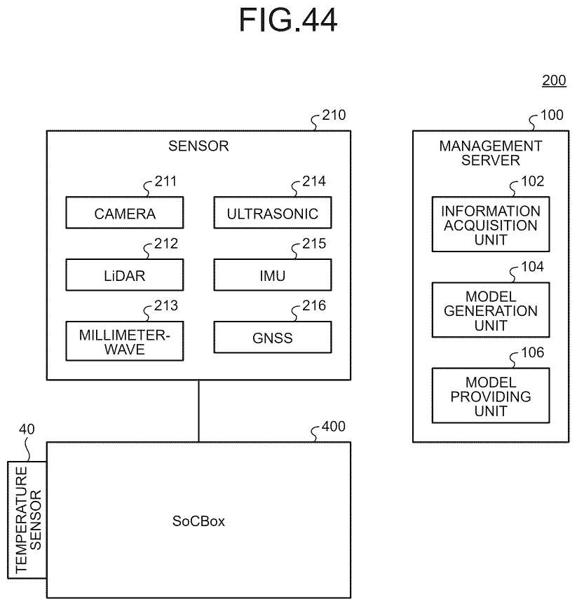

FIG. 44 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling execution device 500 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

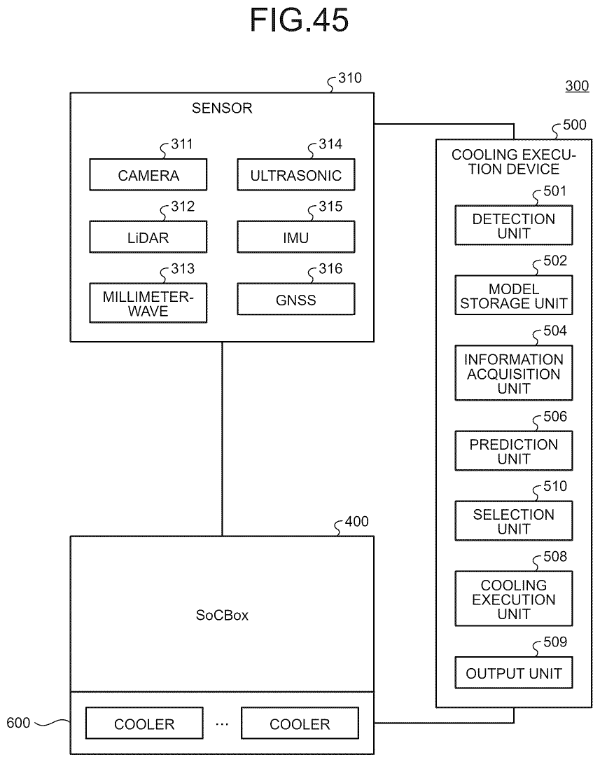

FIG. 45 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling execution device 500 includes a detection unit 501, a model storage unit 502, an information acquisition unit 504, a prediction unit 506, a selection unit 510, a cooling execution unit 508, and an output unit 509. The model storage unit 502 stores the learning model received from the management server 100. The information acquisition unit 504 acquires information acquired by the SoCBox 400.

The detection unit 501 detects a temperature change of the control device that controls the automatic driving of the vehicle and that is mounted on the vehicle. Furthermore, the detection unit 501 may detect the temperature change of each of a plurality of portions of the SoCBox 400. For example, the detection unit 501 can detect the occurrence of an increase or decrease in temperature of one or a plurality of SoCBoxes 400, and detect a numerical value of a changing temperature.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500. Furthermore, the information acquisition unit 504 may acquire a result of information processing related to automatic driving from an external information processing device that performs the information processing related to automatic driving as predetermined information processing of the control device (SoCBox 400). For example, when the external information processing device performs information processing related to control of automatic driving to be originally performed by the control device (SoCBox 400) of the vehicle, the information acquisition unit 504 can acquire a result of the information processing related to the automatic driving from the external information processing device.

The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502.

When the temperature change exceeds a predetermined threshold, the selection unit 510 selects a predetermined driving condition for lowering the temperature of the control device. A specific example of the driving condition selected by the selection unit 510 will now be described.

For example, when the temperature change exceeds a predetermined threshold, the selection unit 510 may select, as a predetermined driving condition, a driving condition for inhibiting a calculation amount related to predetermined information processing of the control device (SoCBox 400). This causes the cooling execution device to inhibit an amount of heat generated by calculation related to information processing and exhibit an effect of cooling the control device.

When the temperature change exceeds a predetermined threshold, the selection unit 510 may select, as a predetermined driving condition, a driving condition for inhibiting a driving speed of automatic driving to a predetermined speed or less. This causes the cooling execution device to inhibit a calculation amount related to the information processing of the automatic driving. The cooling execution device thereby inhibits an amount of heat generated by the calculation, and exhibits an effect of cooling the control device.

Furthermore, when the temperature change exceeds a predetermined threshold, the selection unit 510 may select, as a predetermined driving condition, a driving condition for changing automatic driving to manual driving. This causes the cooling execution device to perform switching to manual driving having a less calculation amount than automatic driving. The cooling execution device thereby inhibits an amount of heat generated by the calculation, and exhibits an effect of cooling the control device.

When the temperature change exceeds a predetermined threshold, the selection unit 510 may select, as a predetermined driving condition, a driving condition for stopping at a predetermined position (e.g., road shoulder) of a road included in a travel route of automatic driving. This causes the cooling execution device to stop automatic driving and inhibit a calculation amount related to the automatic driving. The cooling execution device thereby inhibits an amount of heat generated by the calculation, and exhibits an effect of cooling the control device.

When the temperature change exceeds a predetermined threshold, the selection unit 510 may select, as a predetermined driving condition, a driving condition for inhibiting acquisition of predetermined information to be used for information processing of automatic driving.

This causes the cooling execution device to inhibit acquisition of information to be used for information processing of automatic driving and inhibit a calculation amount related to the automatic driving. The cooling execution device thereby inhibits an amount of heat generated by the calculation, and exhibits an effect of cooling the control device.

The cooling execution unit 508 starts cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SocBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The output unit 509 outputs a predetermined driving condition based on a result of selection of the selection unit 510. Specifically, the output unit 509 may output information on a driving condition for the control device (SoCBox 400) to control the automatic driving of the vehicle based on the driving condition selected by the selection unit 510. Note that the information on the driving condition output by the output unit 509 is not particularly limited as long as the information is in a format that can be used by the control device of the vehicle.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

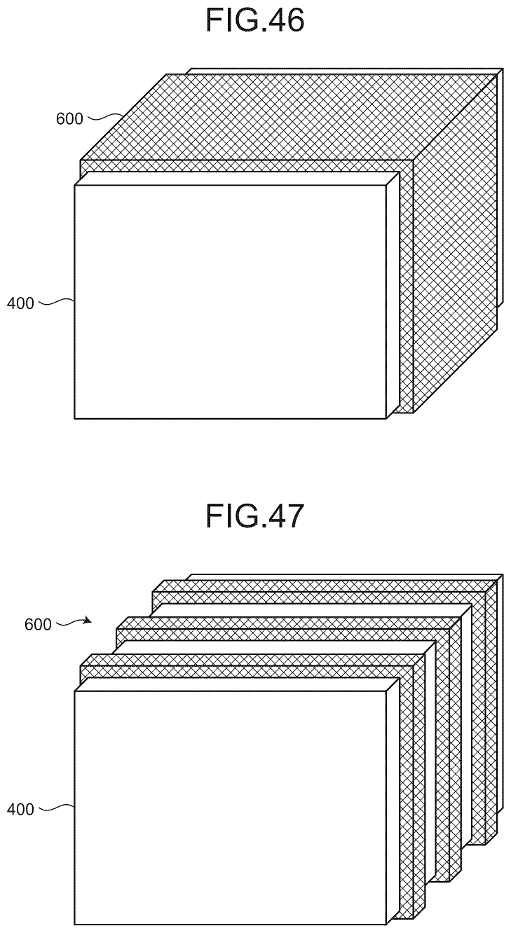

FIG. 46 schematically illustrates an example of the SoCBox 400 and the cooling unit 600. FIG. 46 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 47 schematically illustrates an example of the SoCBox 400 and the cooling unit 600. FIG. 47 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

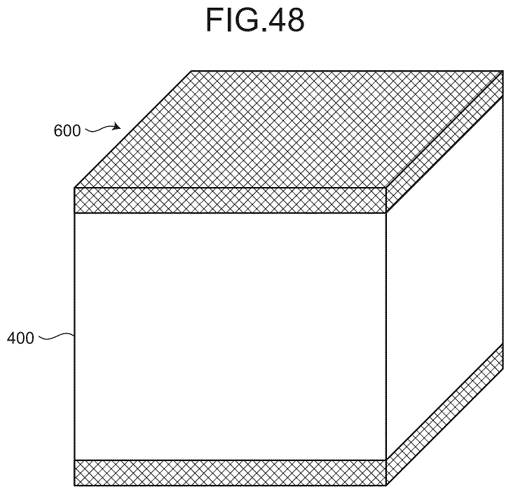

FIG. 48 schematically illustrates an example of the SoCBox 400 and the cooling unit 600. FIG. 48 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Ninth Embodiment

A problem of heat generation arises when a system on chip (SoC) (processing chip) for automatic driving performs advanced arithmetic processing. Therefore, the embodiment provides a technique of cooling a SoCBox, which is a control device, by utilizing artificial intelligence (AI).

Advanced arithmetic in a vehicle is difficult since a SoCBox easily has high temperature (problem for fully automatic driving). For example, the SoCBox includes a plurality of SoCs. As the control of the automatic driving is complicated, processing performed by the SoCs increases. Accordingly, the SoCBox may have a high temperature to cause overheating. Therefore, AI predicts heat dissipation of the SoCBox. Communication is performed with another vehicle traveling near the vehicle before the SoCBox overheats to cause the other vehicle to cover a part of a calculation load of a SoC. The SoCBox is thereby prevented from having high temperature. This enables the advanced arithmetic in the vehicle.

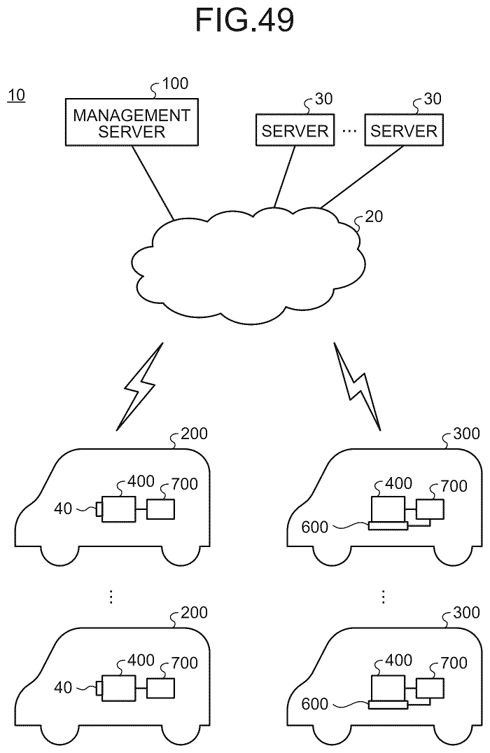

FIG. 49 schematically illustrates an example of a system 10. The system 10 includes a management server 100. The system 10 includes a SoCBox 400. The system 10 includes a cooling device 700. The system 10 includes a cooling unit 600.

The SoCBox 400, the cooling device 700, and the cooling unit 600 are mounted on a vehicle. The SoCBox 400 is a control device including a plurality of SoCs, and controls automatic driving of the vehicle by using sensor values of a plurality of sensors mounted on the vehicle.

An extremely high processing load is put in the control of automatic driving of the vehicle, which may cause the SoCBox 400 to have extremely high temperature. An excessively high temperature of the SoCBox 400 may discourage the normal operation of the SoCBox 400, and impose a negative effect on the vehicle.

The cooling device 700 according to the embodiment predicts a temperature change of the SoCBox 400. The cooling device 700 communicates with another vehicle within a predetermined range based on the temperature change. The cooling device 700 instructs the control device to execute arithmetic regarding the control of automatic driving of the other vehicle with which the communication is performed. For example, when the SoCBox 400 is predicted to start heat generation and a predicted temperature after the heat generation exceeds a preset threshold temperature, the cooling device 700 communicates with another vehicle traveling in parallel near the vehicle. Thereafter, for example, the cooling device 700 groups a plurality of vehicles with which communications are performed. The cooling device 700 instructs the SoCBox 400 to perform arithmetic so that a part of a calculation load of a Soc in a vehicle of a communication source is covered. Furthermore, the cooling device 700 may perform arithmetic regarding automatic driving so that vehicles with which communications are performed complement each other.

When the SoCBox 400 is predicted to have a temperature exceeding a set threshold, the cooling device 700 communicates with a nearby vehicle to cause the vehicle to cover a part of a calculation load or complement calculation loads of each other. The cooling device 700 can thereby reduce the calculation load, and decrease the temperature of the SoCBox 400.

Here, the above-described preset threshold temperature is set as an upper limit temperature at which a plurality of SoCs of the SoCBox 400 can normally perform processing.

Furthermore, the cooling device 700 may determine another vehicle within a range in which communication with the other vehicle can be maintained for a predetermined time as a vehicle within the predetermined range, and communicate with the vehicle. For example, the cooling device 700 determines a vehicle within a range in which a communication unit can perform communication and communication between vehicles can be maintained for a certain time as a vehicle within the predetermined range, and communicates with the vehicle. Note that examples of a method of determining a vehicle within a predetermined range include determining, as a vehicle within the predetermined range, a vehicle that has reacted to predetermined broadcast communication and a vehicle that has been confirmed to be in the vicinity by position information.

Furthermore, the cooling device 700 may start cooling the SoCBox based on the temperature change predicted by the prediction unit. For example, when the SoCBox 400 is predicted to have a temperature exceeding the above-described threshold temperature, the cooling device 700 starts cooling the SoCBox 400 with an air cooler and the like.

The cooling device 700 communicates with the above-described other vehicle, and reduces a calculation load. In addition, the cooling device 700 cools the SoCBox 400 from the outside. The cooling device 700 can thereby rapidly cool the SoCBox 400.

The cooling device 700 may predict the temperature change of the SoCBox 400 by AI. Note that the temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400, a temperature sensor 40, and the cooling device 700 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30.

The cooling device 700 acquires, from the plurality of sensors and the plurality of types of servers 30 or the SoCBox 400, the sensor values of the plurality of sensors mounted on the vehicle 200 and the external information received from the plurality of types of servers 30. The sensor values and the external information have been acquired by the SoCBox 400. The cooling device 700 inputs the acquired information to the learning model. The cooling device 700 thereby predicts the temperature change of the SoCBox 400.

For example, when the SoCBox 400 is predicted to start heat generation and a predicted temperature after the heat generation exceeds a preset threshold temperature, the cooling device 700 communicates with another vehicle traveling in the vicinity, and reduces the calculation load of the SoCBox 400. The temperature of the SoCBox 400 thereby decreases.

The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling unit according to the embodiment. The SoCBox 400, the cooling device 700, and the cooling unit 600 are mounted on the vehicle 300. The cooling device 700 may receive the learning model generated by the management server 100 from the management server 100, and store the learning model.

The SoCBox 400, the cooling device 700, the management server 100, and the servers 30 may communicate via a network 20. The network 20 may include a vehicle network. The network 20 may include the Internet. The network 20 may include a local area network (LAN).

The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

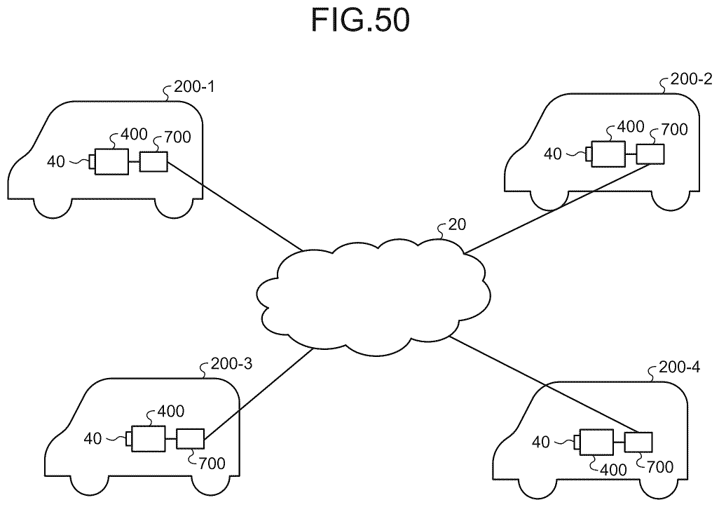

FIG. 50 is an explanatory diagram of a state in which communication is performed between vehicles in the embodiment. As described above, when the SoCBox 400 is predicted to have a temperature exceeding a preset threshold temperature, the cooling device 700 communicates with another vehicle traveling in the vicinity. The cooling device 700 instructs the SoCBox 400 to execute arithmetic so that the vehicle of a communication destination covers a part of the calculation load of a SoC of the vehicle of the communication source.

In an example of FIG. 50, a vehicle 200-2, a vehicle 200-3, and a vehicle 200-4 are traveling near a vehicle 200-1 at similar speeds. Then, since the SoCBox 400 of the vehicle 200-1 is predicted to have a temperature exceeding a threshold temperature, a communication unit of 200-1 groups the vehicles 200-1 to 200-4 to form the network 20.

After the network 20 is formed, the cooling device 700 of a vehicle of a communication destination gives an instruction to perform arithmetic so that a part of a calculation load of the SoCBox 400 of a vehicle of a communication source is covered. This causes SoCs of the vehicles 200-2 to 200-4 of communication destinations to cover the part of the calculation load of the Soc in the vehicle 200-1 of the communication source. Thereby, the calculation load of the Soc in the vehicle 200-1 of the communication source is reduced, and the temperature of the SoCBox 400 of the vehicle 200-1 decreases.

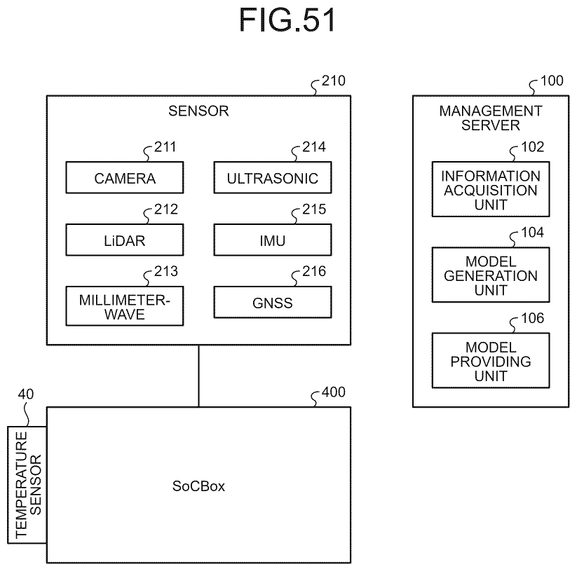

FIG. 51 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210. Furthermore, the SoCBox 400 may execute communication via the network 20. The SoCBox 400 receives external information from each of the plurality of servers 30 via the network 20. Then, the SoCBox 400 controls the automatic driving of the vehicle 200 and the vehicle 300 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model. The model generation unit 104 executes machine learning by using, as learning data, information acquired by the SoCBox 400 and the temperature change of the SoCBox 400 at the time when the SoCBox 400 has acquired the information. The model generation unit 104 thereby generates the learning model in which the information acquired by the SoCBox 400 is used as input and the temperature change of the SoCBox 400 is used as output.

The model providing unit 106 provides the learning model generated by the model generation unit 104. The model providing unit 106 may transmit the learning model to the cooling device 700 mounted on the vehicle 200 and the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled.

The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

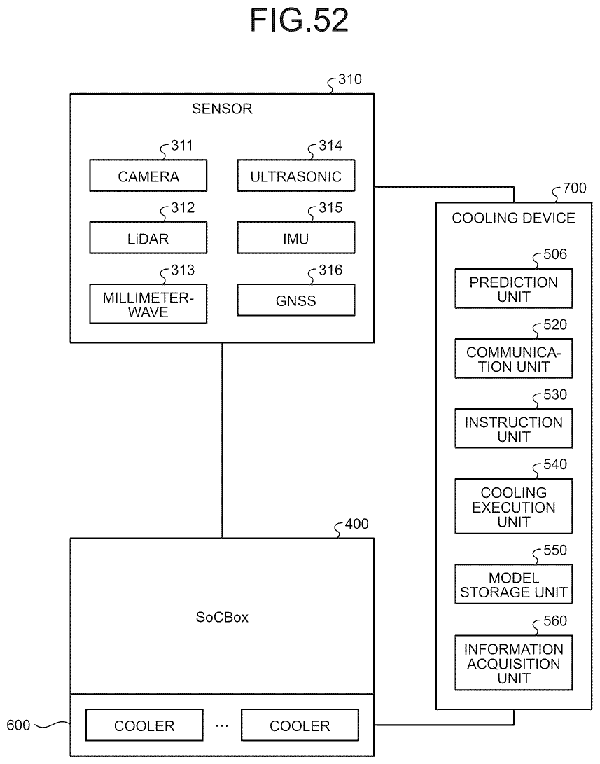

FIG. 52 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling device 700 includes a prediction unit 506, a communication unit 520, an instruction unit 530, a cooling execution unit 540, a model storage unit 550, and an information acquisition unit 560. The prediction unit 506 predicts a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 560 to be described later to the learning model stored in the model storage unit 550 to be described later.

The communication unit 520 communicates with another vehicle within a predetermined range based on the temperature change predicted by the prediction unit 506. For example, when the prediction unit 506 predicts that the SoCBox 400 has a temperature exceeding a preset threshold temperature, the communication unit 520 communicates with another vehicle determined within the above-described predetermined range to form the network 20.

The instruction unit 530 instructs the control device to execute arithmetic regarding the control of automatic driving of the other vehicle with which the communication unit 520 is communicating. For example, when the vehicle of the instruction unit 530 is connected for communication by another vehicle, the instruction unit 530 determines whether or not arithmetic of a part of the calculation load of a Soc in the other vehicle of the communication source can be executed with reference to space of resources of a SoC of the vehicle of the instruction unit 530 itself. Then, for example, when determining that the arithmetic of a part of the calculation load of the Soc in the other vehicle of the communication source can be executed, the instruction unit 530 instructs the SoCBox 400 of the vehicle of the instruction unit 530 itself to execute the arithmetic of a part of the calculation load of the Soc in the other vehicle of the communication source.

The cooling execution unit 540 starts cooling the SoCBox 400 based on the temperature change of the SoCBox 400 predicted by the prediction unit 506. For example, when the prediction unit 506 predicts that the temperature of the SoCBox 400 is higher than a predetermined threshold, the cooling execution unit 540 starts cooling the SoCBox 400.

The cooling execution unit 540 may cool the SoCBox 400 by using the cooling unit 600 to be described later. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The model storage unit 550 stores the learning model received from the management server 100. The information acquisition unit 504 acquires information acquired by the SoCBox 400.

The information acquisition unit 560 acquires, from the sensor 310 or the SoCBox 400, sensor information acquired by the SoCBox 400 from the sensor 310. For example, the information acquisition unit 560 may receive, from the SoCBox 400, the sensor information acquired by the SoCBox 400 from the sensor 310.

The information acquisition unit 560 may receive, from the sensor 310, the same sensor information as the sensor information acquired by the SoCBox 400 from the sensor 310. In this case, each of the sensors of the sensor 310 may transmit sensor information to each of the SoCBox 400 and the cooling device 700.

The information acquisition unit 560 acquires, from the servers 30 or the SoCBox 400, external information acquired by the SoCBox 400 from the servers 30. The information acquisition unit 560 may receive, from the SoCBox 400, the external information received by the SoCBox 400 from the servers 30. The information acquisition unit 560 may receive, from the servers 30, the same external information as the external information received by the SoCBox 400 from the servers 30. In this case, the servers 30 may transmit external information to each of the SoCBox 400 and the cooling device 700.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 540 may cool the SoCBox 400 by using a cooler suitable for the level of the temperature of the SoCBox 400 predicted by the prediction unit 506. For example, as the temperature of the SoCBox 400 increases, the cooling execution unit 508 cools the SoCBox 400 by using more coolers.

In a specific example, when predicting that the SoCBox 400 has a temperature exceeding a first threshold, the cooling execution unit 540 starts cooling using one of the plurality of coolers. When predicting that the SoCBox 400 has an increasing temperature exceeding a second threshold, the cooling execution unit 540 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

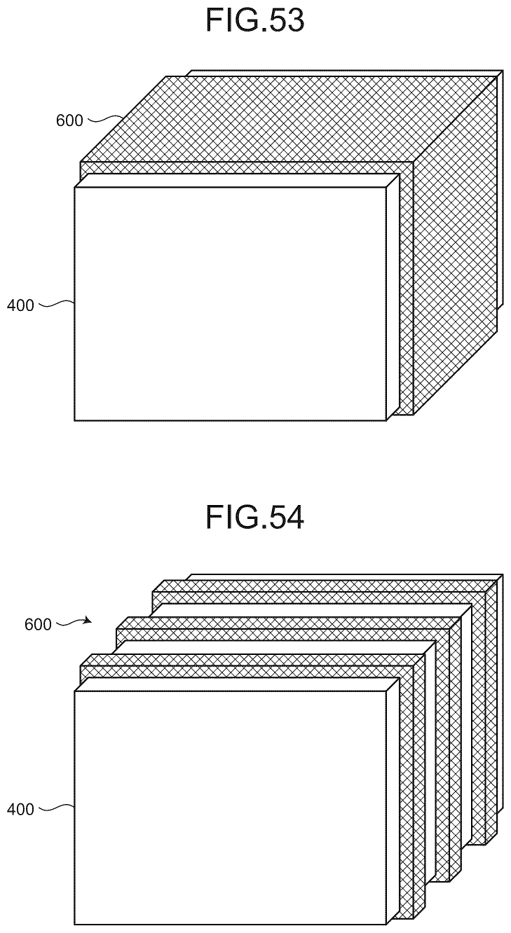

FIG. 53 schematically illustrates an example of the SoCBox 400 and the cooling unit 600. FIG. 53 illustrates a case where the cooling unit 600 includes one cooler. When predicting that the SoCBox 400 is starting heat generation or predicting that the SoCBox 400 has a temperature exceeding a predetermined threshold, the cooling device 700 starts cooling with the cooling unit 600. The cooling device 700 can thereby cool the entire SoCBox 400.

FIG. 54 schematically illustrates an example of the SoCBox 400 and the cooling unit 600. FIG. 54 illustrates a case where the cooling unit 600 includes a plurality of coolers each of which cools each of a plurality of portions of the SoCBox 400.

When predicting that one of a plurality of portions of the SoCBox 400 is starting heat generation or predicting that one of the plurality of portions has a temperature exceeding a predetermined threshold on the prediction of a temperature change of each of the plurality of portions, the cooling device 700 executes cooling using only a cooler suitable for the portion. The cooling device 700 can thereby perform efficient cooling.

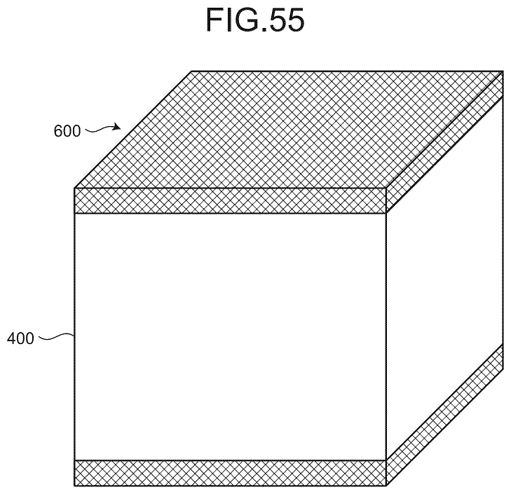

FIG. 55 schematically illustrates an example of the SoCBox 400 and the cooling unit 600. FIG. 55 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling device 700 executes cooling using only a cooler suitable for the portion. The cooling device 700 can thereby perform efficient cooling.

Furthermore, as the SoCBox 400 has an increasing temperature, the cooling device 700 increases the number of coolers to be used. That is, in the example, first, cooling using one of the two types of coolers is started. When the SoCBox 400 has a still increasing temperature, cooling using the other cooler is started. Energy to be used for cooling can thereby be made more efficient.

### 10th Embodiment

A problem of heat generation arises when a system on chip (SoC) for automatic driving performs advanced arithmetic processing. Therefore, the embodiment provides synchronized burst chilling, which is a technique of optimizing rapid cooling of a SoCBox by utilizing artificial intelligence (AI).

Advanced arithmetic in a vehicle is difficult since a SoCBox easily has high temperature (problem for fully automatic driving). Therefore, it is conceivable that AI predicts heat dissipation of the SoCBox to cool the SoCBox. For example, AI predicts heat dissipation of the SoCBox and performs cooling simultaneously with the heat dissipation to prevent the SoCBox from having high temperature. This enables the advanced arithmetic in the vehicle.

In the case, cooling timing is desirably optimized. For example, the moment when the computing power of the SoCBox is maximized is predicted, and the cooling device is controlled with optimal timing. Furthermore, for example, the time from a trigger of cooling to actual cooling is inversely calculated and considered. Furthermore, for example, the degree of cooling is adjusted in accordance with a risk rate. In a specific example, control is performed such that cooling is performed when the risk rate exceeds 30%, cooling is weakened when the risk rate is 20% or less, and cooling is intensified when the risk rate exceeds 50%.

AI predicts heat dissipation of the SoCBox and performs cooling simultaneously with the heat dissipation to prevent the SoCBox from having high temperature. This enables the advanced arithmetic in the vehicle. Furthermore, cooling can be efficiently performed in consideration of necessity, time, and risk.

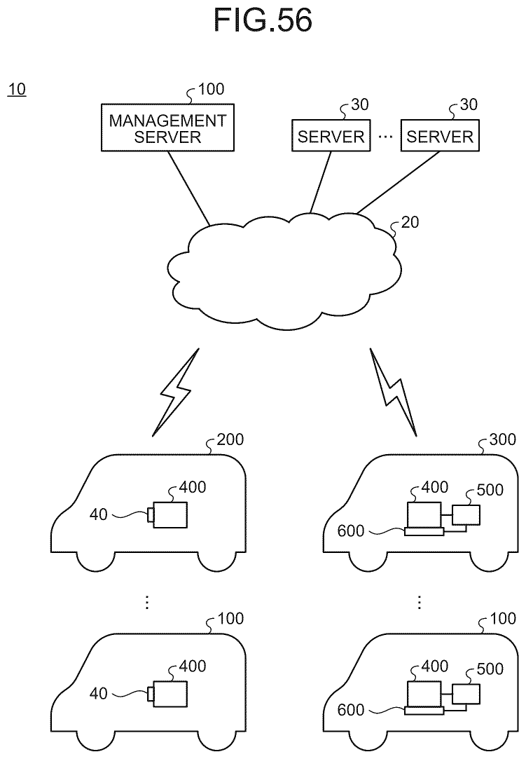

FIG. 56 schematically illustrates an example of a system 10. The system 10 includes a management server 100. The system 10 includes a SoCBox 400. The system 10 includes a cooling execution device 500. The system 10 includes a cooling unit 600.

The SoCBox 400, the cooling execution device 500, and the cooling unit 600 are mounted on a vehicle. The SoCBox 400 controls automatic driving of the vehicle by using sensor values of a plurality of sensors mounted on the vehicle. An extremely high processing load is put in the control of automatic driving of the vehicle, which may cause the SoCBox 400 to have extremely high temperature.

An excessively high temperature of the SoCBox 400 may discourage the normal operation of the SoCBox 400, and impose a negative effect on the vehicle.

For example, the cooling execution device 500 according to the embodiment predicts a temperature change of the SoCBox 400, and starts cooling the SoCBox 400 based on the temperature change. For example, when predicting that the SoCBox 400 is starting heat generation, the cooling execution device 500 immediately starts cooling the SoCBox 400 accordingly. The SoCBox 400 can be reliably prevented from having high temperature by starting cooling earlier than or simultaneously with the start of heat generation. Furthermore, energy required for cooling can be reduced as compared with that in a case where the SoCBox 400 is constantly cooled.

The cooling execution device 500 may predict the temperature change of the SoCBox 400 by AI. The temperature change of the SoCBox 400 may be learned by using data collected by a vehicle 200. For example, the management server 100 collects data from the vehicle 200, and executes learning. A subject that executes learning is not limited to the management server 100, and may be another device.

The SoCBox 400 and a temperature sensor 40 are mounted on the vehicle 200. The temperature sensor 40 measures the temperature of the SoCBox 400. The SoCBox 400 controls automatic driving of the vehicle 200 by using sensor values of a plurality of sensors mounted on the vehicle 200 and external information received from a plurality of types of servers 30. The servers 30 may be examples of an external device. Examples of the plurality of types of servers 30 include a server that provides traffic information and a server that provides weather information. The SoCBox 400 transmits, to the management server 100, the sensor values, the external information, and the like used for the control of the automatic driving, and the temperature change of the SoCBox 400 at the time of the control.

The management server 100 executes learning by using information received from one or a plurality of SoCBoxes 400. The management server 100 executes machine learning by using, as learning data, information such as the sensor values and the external information acquired by the SoCBox 400 and the temperature change of the SoCBox 400 at the time when the SoCBox 400 has acquired these pieces of information. The management server 100 thereby generates a learning model in which the information acquired by the SoCBox 400 is used as input and the temperature change of the SoCBox 400 is used as output.

A vehicle 300 has a cooling function according to the embodiment. The SoCBox 400, the cooling execution device 500, and the cooling unit 600 are mounted on the vehicle 300. The cooling execution device 500 may receive the learning model generated by the management server 100 from the management server 100, and store the learning model.

The cooling execution device 500 may acquire, from the plurality of sensors and the plurality of types of servers 30 or the SoCBox 400, the sensor values of the plurality of sensors mounted on the vehicle 300 and the external information received from the plurality of types of servers 30. The sensor values and the external information have been acquired by the SoCBox 400. The cooling execution device 500 may input the acquired information to the learning model. The cooling execution device 500 may thereby predict the temperature change of the SoCBox 400.

When predicting that the SoCBox 400 is starting heat generation or predicting that the SoCBox 400 has a temperature higher than a predetermined threshold, the cooling execution device 500 may start cooling the SoCBox 400 with the cooling unit 600.

When predicting the temperature change of the SoCBox 400, the cooling execution device 500 may predict the computing power of the SoCBox 400 in a calculation process. For example, the cooling execution device 500 predicts a change in the computing power of the SoCBox 400 by AI, and predicts a temperature change of the SocBox 400 based on the prediction result. In a specific example, the cooling execution device 500 predicts the moment when the computing power of the SoCBox 400 is maximized by AI. The cooling execution device 500 predicts the temperature change of the SoCBox 400 in consideration of the temperature change of the SoCBox 400 caused by the maximized computing power of the SoCBox 400.

The management server 100 may execute machine learning by using, as learning data, information such as the sensor values and the external information acquired by the SoCBox 400 and the actually measured computing power of the SoCBox 400. The management server 100 may thereby generate a learning model in which the information acquired by the SoCBox 400 is used as input and the computing power of the SoCBox 400 is used as output. The cooling execution device 500 may predict a change in the computing power of the SoCBox 400 by using the learning model.

Furthermore, the cooling execution device 500 according to the embodiment may predict a change in the computing power of the SoCBox 400, and start cooling the SoCBox 400 based on the change in the computing power. For example, the cooling execution device 500 predicts the moment when the computing power of the SoCBox 400 is maximized, and starts cooling the SoCBox 400 based on the prediction result. In a specific example, the cooling execution device 500 predicts the moment when the computing power of the SoCBox 400 is maximized, and starts cooling the SoCBox 400 at the timing when the predicted moment comes. Furthermore, for example, the cooling execution device 500 predicts the moment when the computing power of the SoCBox 400 is maximized, and starts cooling the SoCBox 400 at the timing a predetermined time earlier than the predicted moment.

The cooling execution device 500 according to the embodiment may cool the SoCBox 400 in consideration of the time from a trigger of cooling to actual cooling. For example, when starting cooling the SoCBox 400 in a situation in which the SoCBox 400 is placed, the cooling execution device 500 predicts, by AI, a time until the SoCBox 400 is actually cooled, and controls the timing when cooling the SoCBox 400 is started in accordance with the prediction result. In a specific example, the cooling execution device 500 starts cooling the SoCBox 400 at the timing a predicted time earlier than the timing when cooling the SoCBox 400 is desired to be actually started. Even if cooling is started with the timing when cooling the SoCBox 400 is desired to be actually started as a trigger, the start of the cooling is delayed if there is a time lag before the SoCBox 400 is actually cooled. Prediction as described above enables the SoCBox 400 to be actually cooled at the timing when the SoCBox 400 is desired to be actually cooled.

The management server 100 executes machine learning by using, as learning data, information such as the sensor values and the external information acquired by the SoCBox 400 and the time until the SoCBox 400 is cooled in a case where cooling the SoCBox 400 is started at the time when the SoCBox 400 acquires the information. The management server 100 may thereby generate a learning model in which the information acquired by the SoCBox 400 is used as input and the time until the SoCBox 400 is actually cooled in a case where cooling the SoCBox 400 is started is used as output. The cooling execution device 500 may control a trigger of cooling the SoCBox 400 by using the learning model.

For example, the cooling execution device 500 according to the embodiment may adjust the degree of cooling the SoCBox 400 in accordance with a risk rate. The risk rate may be, for example, a probability that the SoCBox 400 does not normally function due to a high temperature of the SoCBox 400. The risk rate may be, for example, a probability that the SoCBox 400 does not normally function due to a high temperature of the SoCBox 400 and an influence is exerted on normal automatic driving of a vehicle controlled by the SoCBox 400.

The risk rate may be, for example, a probability that the SoCBox 400 does not normally function due to a high temperature of the SoCBox 400 and an influence is exerted on normal automatic driving of a vehicle controlled by the SoCBox 400 to cause an accident. For example, different risk rates are presented between a case where the SoCBox 400 does not normally function due to a high temperature at the time when the vehicle is traveling in an area with good weather and nothing around and a case where the SoCBox 400 does not normally function due to a high temperature at the time when the vehicle is traveling in a crowded area such as a city with bad weather.

For example, the cooling execution device 500 preliminarily stores a first threshold and a second threshold higher than the first threshold for the risk rate. Then, when the risk rate is lower than a first threshold, the cooling execution device 500 cools the SoCBox 400 with a first cooling intensity. When the risk rate is higher than the first threshold and lower than a second threshold, the cooling execution device 500 cools the SoCBox 400 with a second cooling intensity higher than the first cooling intensity. When the risk rate is higher than the second threshold, the cooling execution device 500 cools the SoCBox 400 with a third cooling intensity higher than the second cooling intensity. This enables cooling the SoCBox 400 and optimizing energy required for cooling in accordance with a risk rate. Note that the cooling intensity is not limited to having three stages.

The SoCBox 400, the cooling execution device 500, the management server 100, and the servers 30 may communicate via a network 20. The network 20 may include a vehicle network. The network 20 may include the Internet. The network 20 may include a local area network (LAN). The network 20 may include a mobile communication network. The mobile communication network may conform to one of a 5th generation (5G) communication system, a long term evolution (LTE) communication system, a 3rd generation (3G) communication system, and a communication system after a 6th generation (6G) communication system.

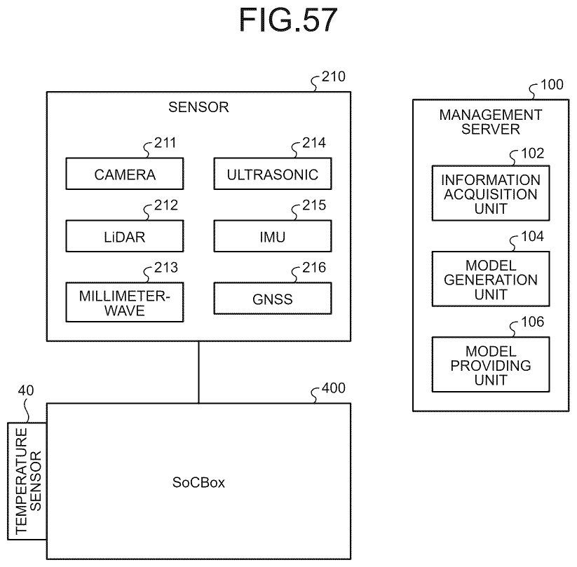

FIG. 57 is an explanatory diagram illustrating a learning phase in the system 10. Here, a sensor 210 mounted on the vehicle 200 is illustrated as including a camera 211, a light detection and ranging (LiDAR) 212, a millimeter-wave sensor 213, an ultrasonic sensor 214, an IMU sensor 215, and a global navigation satellite system (GNSS) sensor 216. The vehicle 200 is not required to include all the sensors. The vehicle 200 does not have to include some of the sensors. The vehicle 200 may include a sensor other than the sensors.

The SoCBox 400 acquires sensor information from each of the sensors included in the sensor 210.

Furthermore, the SoCBox 400 may execute communication via the network 20. The SoCBox 400 receives external information from each of the plurality of servers 30 via the network 20. Then, the SoCBox 400 controls the automatic driving of the vehicle 200 by using the acquired information.

The temperature sensor 40 measures a temperature change of the SoCBox 400. The SoCBox 400 transmits, to the management server 100, the sensor information received from the sensor 210, the external information received from the servers 30, and the temperature change measured by the temperature sensor 40 at the time when these pieces of information have been acquired and the automatic driving has been controlled.

The SoCBox 400 records the computing power of the SoCBox 400. The SoCBox 400 may regularly or irregularly record the computing power of the SoCBox 400. The SoCBox 400 may record the sensor information received from the sensor 210, the external information received from the servers 30, and the computing power of the SoCBox 400 at the time when these pieces of information are acquired and the automatic driving is controlled, and transmit these pieces of information and the computing power to the management server 100.

The management server 100 includes an information acquisition unit 102, a model generation unit 104, and a model providing unit 106. The information acquisition unit 102 acquires various pieces of information. The management server 100 may receive information transmitted by the SoCBox 400.

The model generation unit 104 executes machine learning using the information acquired by the information acquisition unit 102, and generates a learning model.

The model generation unit 104 may execute machine learning by using, as learning data, information acquired by the SoCBox 400 and the temperature change of the SoCBox 400 at the time when the SoCBox 400 has acquired the information. The model generation unit 104 may thereby generate the learning model in which the information acquired by the SoCBox 400 is used as input and the temperature change of the SoCBox 400 is used as output.

The model generation unit 104 may execute machine learning by using, as learning data, information acquired by the SoCBox 400 and the computing power of the SoCBox 400 at the time when the SoCBox 400 has acquired the information. The model generation unit 104 may thereby generate the learning model in which the information acquired by the SoCBox 400 is used as input and the computing power of the SoCBox 400 is used as output.

The model generation unit 104 executes machine learning by using, as learning data, information acquired by the SoCBox 400 and the time until the SoCBox 400 is cooled in a case where cooling the SoCBox 400 is started at the time when the SoCBox 400 acquires the information. The model generation unit 104 may thereby generate a learning model in which the information acquired by the SoCBox 400 is used as input and the time until the SoCBox 400 is cooled in a case where cooling the SoCBox 400 is started is used as output.

The model providing unit 106 provides the learning model generated by the model generation unit 104. The model providing unit 106 may transmit the learning model to the cooling execution device 500 mounted on the vehicle 300.

The system 10 may predict a temperature change of each of a plurality of portions of the SoCBox 400. In this case, the vehicle 200 may include a plurality of temperature sensors 40 each of which measures a temperature change of each of the plurality of portions of the SoCBox 400. The SoCBox 400 may transmit, to the management server 100, the sensor information received from the sensor 210, the external information received from the servers 30, and the temperature change measured by the plurality of temperature sensors 40 at the time when these pieces of information have been acquired and the automatic driving has been controlled. The model generation unit 104 executes machine learning by using, as learning data, information acquired by the SoCBox 400 and the temperature change of each of the plurality of portions of the SoCBox 400 at the time when the SoCBox 400 has acquired the information. The model generation unit 104 thereby generates the learning model in which the information acquired by the SoCBox 400 is used as input and the temperature change of each of the plurality of portions of the SoCBox 400 is used as output.

The cooling unit 600 may be mounted on the vehicle 200 to collect data on cooling of the SoCBox 400.

For example, when the cooling unit 600 cools the SoCBox 400, the temperature sensor 40 measures the time from the timing of a trigger to the cooling unit 600 until the SoCBox 400 is actually cooled. The SoCBox 400 transmits, to the management server 100, the sensor information received from the sensor 210, the external information received from the servers 30, and the time from the timing of a trigger to the cooling unit 600 until the SoCBox 400 is actually cooled in a case where the cooling unit 600 cools the SoCBox 400 at the time when these pieces of information have been acquired. The model generation unit 104 of the management server 100 executes machine learning by using, as learning data, information such as the sensor values and the external information acquired by the SoCBox 400 and the time until the SoCBox 400 is actually cooled in a case where cooling the SoCBox 400 is started at the time when the SoCBox 400 acquires the information. The model generation unit 104 may thereby generate a learning model in which the information acquired by the SoCBox 400 is used as input and the time until the SoCBox 400 is actually cooled in a case where cooling the SoCBox 400 is started is used as output. The model providing unit 106 may transmit the learning model to the cooling execution device 500 mounted on the vehicle 300.

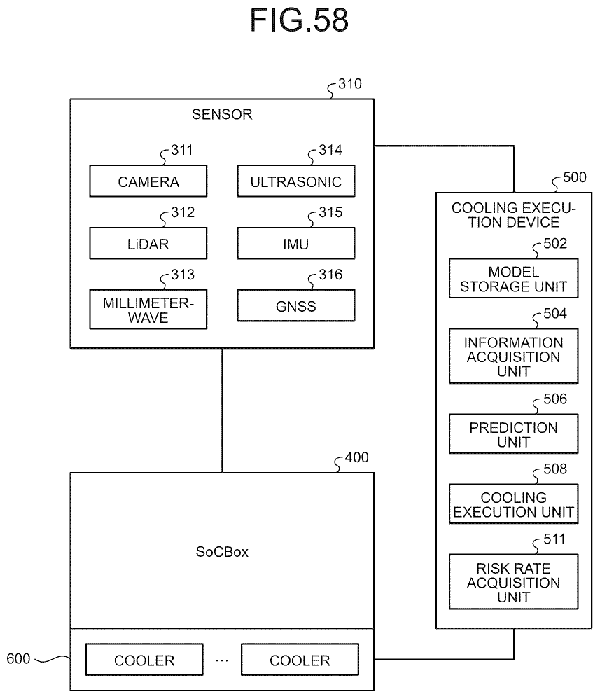

FIG. 58 is an explanatory diagram illustrating a cooling execution phase in the system 10. Here, a sensor 310 mounted on the vehicle 300 is illustrated as including a camera 311, a LiDAR 312, a millimeter-wave sensor 313, an ultrasonic sensor 314, an IMU sensor 315, and a GNSS sensor 316. The vehicle 300 is not required to include all the sensors. The vehicle 300 does not have to include some of the sensors. The vehicle 200 may include a sensor other than the sensors.

The cooling execution device 500 includes a model storage unit 502, an information acquisition unit 504, a prediction unit 506, a cooling execution unit 508, and a risk rate acquisition unit 511. The model storage unit 502 stores the learning model received from the management server 100. The information acquisition unit 504 acquires information acquired by the SoCBox 400.

The information acquisition unit 504 acquires, from the sensor 310 or the SoCBox 400, sensor information acquired by the SoCBox 400 from the sensor 310. For example, the information acquisition unit 504 may receive, from the SoCBox 400, the sensor information acquired by the SoCBox 400 from the sensor 310. The information acquisition unit 504 may receive, from the sensor 310, the same sensor information as the sensor information acquired by the SoCBox 400 from the sensor 310. In this case, each of the sensors of the sensor 310 may transmit sensor information to each of the SoCBox 400 and the cooling execution device 500.

The information acquisition unit 504 acquires, from the servers 30 or the SoCBox 400, external information acquired by the SoCBox 400 from the servers 30. The information acquisition unit 504 may receive, from the SoCBox 400, the external information received by the SoCBox 400 from the servers 30. The information acquisition unit 504 may receive, from the servers 30, the same external information as the external information received by the SoCBox 400 from the servers 30. In this case, the servers 30 may transmit external information to each of the SoCBox 400 and the cooling execution device 500.

The prediction unit 506 may predict a temperature change of the SoCBox 400. The prediction unit 506 may predict the temperature change of the SoCBox 400 by AI. For example, the prediction unit 506 predicts the temperature change of the SoCBox 400 by inputting information acquired by the information acquisition unit 504 to the learning model stored in the model storage unit 502.

When predicting the temperature change of the SoCBox 400, the prediction unit 506 may predict the computing power of the SoCBox 400 in a calculation process. For example, the prediction unit 506 predicts the computing power of the SoCBox 400 by inputting information acquired by the information acquisition unit 504 to the learning model stored in the model storage unit 502, and predicts the temperature change of the SoCBox 400 based on the prediction result. In a specific example, the prediction unit 506 predicts the moment when the computing power of the SoCBox 400 is maximized. The prediction unit 506 predicts the temperature change of the SoCBox 400 in consideration of the temperature change of the SoCBox 400 caused by the maximized computing power of the SoCBox 400.

The cooling execution unit 508 may start cooling the SoCBox 400 based on the temperature change of the SoCBox 400 predicted by the prediction unit 506. For example, when the prediction unit 506 predicts that the SoCBox 400 is starting heat generation, the cooling execution unit 508 starts cooling the SoCBox 400. For example, when the prediction unit 506 predicts that the temperature of the SoCBox 400 is higher than a predetermined threshold, the cooling execution unit 508 starts cooling the SoCBox 400.

The cooling execution unit 508 may cool the SoCBox 400 by using the cooling unit 600. The cooling unit 600 may cool the SoCBox 400 with an air cooler. The cooling unit 600 may cool the SoCBox 400 with a water cooler. The cooling unit 600 may cool the SoCBox 400 with a liquid nitrogen cooler.

The cooling unit 600 may include a plurality of types of coolers. For example, the cooling unit 600 includes a plurality of types of air coolers. For example, the cooling unit 600 includes a plurality of types of water coolers. For example, the cooling unit 600 includes a plurality of types of liquid nitrogen coolers. The cooling unit 600 may include a plurality of one or a plurality of types of air coolers, one or a plurality of types of water coolers, and one or a plurality of liquid nitrogen coolers.

Each of a plurality of coolers may be arranged to cool a different portion of the SoCBox 400. The prediction unit 506 may predict a temperature change of each of a plurality of portions of the SoCBox 400 by using the information acquired by the information acquisition unit 504. The cooling execution unit 508 may start cooling the SoCBox 400 by using a cooler selected from the plurality of coolers each of which cools each of the plurality of portions of the SoCBox 400 based on the prediction result from the prediction unit 506.

The cooling execution unit 508 may cool the SoCBox 400 by using a cooler suitable for the level of the temperature of the SoCBox 400 predicted by the prediction unit 506. For example, as the temperature of the SocBox 400 increases, the cooling execution unit 508 cools the SoCBox 400 by using more coolers. In a specific example, when predicting that the SoCBox 400 has a temperature exceeding a first threshold, the cooling execution unit 508 starts cooling using one of the plurality of coolers. When predicting that the SoCBox 400 has an increasing temperature exceeding a second threshold, the cooling execution unit 508 uses an increased number of coolers.

The cooling execution unit 508 may cool the SoCBox 400 by using a stronger cooler as the temperature of the SoCBox 400 increases. For example, when the temperature of the SoCBox 400 is predicted to exceed the first threshold, the cooling execution unit 508 starts cooling using an air cooler. When the temperature of the SoCBox 400 is predicted to still increase and exceed the second threshold, the cooling execution unit 508 starts cooling using a water cooler. When the temperature of the SoCBox 400 is predicted to still yet increase and exceed a third threshold, the cooling execution unit 508 starts cooling using a liquid nitrogen cooler.

The SoCBox 400 may include a plurality of processing chips. The plurality of processing chips may be arranged at different positions of the SoCBox 400. Each of the plurality of coolers may be arranged at a position corresponding to each of the plurality of processing chips.

For example, when the number of processing chips to be used changes in accordance with a situation of the control of automatic driving, a cooler suitable for the processing chips being used performs cooling. Efficient cooling can thus be performed.

The prediction unit 506 may predict a change in the computing power of the SoCBox 400. The prediction unit 506 may predict the change in the computing power of the SoCBox 400 by AI. For example, the prediction unit 506 predicts the computing power of the SoCBox 400 by inputting information acquired by the information acquisition unit 504 to the learning model stored in the model storage unit 502. In a specific example, the prediction unit 506 may predict the moment when the computing power of the SoCBox 400 is maximized.

The cooling execution unit 508 may start cooling the SoCBox 400 based on a change in the computing power of the SoCBox 400 predicted by the prediction unit 506. For example, the cooling execution unit 508 starts cooling the SoCBox 400 based on the moment when the computing power of the SoCBox 400 is maximized, which has been predicted by the prediction unit 506. In a specific example, the cooling execution unit 508 starts cooling the SoCBox 400 at the moment when the computing power of the SoCBox 400 is maximized. This enables the SoCBox 400 to start to be cooled with the maximized computing power of the SoCBox 400 and the maximized heat generation amount as triggers. Cooling can thus be efficiently performed.

Furthermore, in a specific example, when a state in which the computing power of the SoCBox 400 is higher than a predetermined threshold continues for a predetermined time, the cooling execution unit 508 starts cooling the SoCBox 400. When the computing power of the SoCBox 400 increases but then decreases soon, an excessively high temperature of the SoCBox 400 can be avoided. When the computing power of the SoCBox 400 continues to be high to some extent, the temperature of the SoCBox 400 may continue to increase. The cooling execution unit 508 can prevent such a temperature increase.

The prediction unit 506 may predict the time until the temperature of the SoCBox 400 becomes higher than a predetermined temperature from the result of prediction of the moment when the computing power of the SoCBox 400 is maximized. The cooling execution unit 508 may start cooling the SoCBox 400 based on the time predicted by the prediction unit 506. For example, the cooling execution unit 508 performs inverse calculation from the time when the temperature of the SoCBox 400 becomes higher than a predetermined temperature. The cooling execution unit 508 determines the timing when the SoCBox 400 starts to be cooled such that the temperature of the SoCBox 400 does not become higher than the predetermined temperature. The cooling execution unit 508 starts cooling the SoCBox 400 at the determined timing.

The cooling execution unit 508 may cool the SoCBox 400 in consideration of the time from a trigger of cooling to actual cooling. For example, when starting cooling the SoCBox 400 in a situation in which the SoCBox 400 is placed, the cooling execution unit 508 predicts, by AI, a time until the SoCBox 400 is actually cooled, and controls the timing when cooling the SoCBox 400 is started in accordance with the prediction result. The cooling execution unit 508 may predict the time by inputting information acquired by the information acquisition unit 504 to a learning model in which information acquired by the SoCBox 400 is used as input and the time until the SoCBox 400 is actually cooled in a case where the SoCBox 400 starts cooling is used as output. The learning model is stored in the model storage unit 502. In a specific example, the cooling execution unit 508 instructs the cooling unit 600 to start cooling at the timing a predicted time earlier than the timing when cooling the SoCBox 400 is desired to be actually started.

The risk rate acquisition unit 511 acquires a risk rate. The risk rate acquisition unit 511 may calculate the risk rate by using information acquired by the information acquisition unit 504. The risk rate acquisition unit 511 calculates the risk rate by calculating the possibility of occurrence of an accident from the temperature of the SoCBox 400 predicted by the prediction unit 506 by using, for example, relational data indicating the relation between the temperature of the SoCBox 400 and a situation of occurrence of an accident of a vehicle mounted with the SoCBox 400.

For example, the risk rate acquisition unit 511 calculates the risk rate based on the position of the vehicle 300. The risk rate acquisition unit 511 calculates the risk rate such that a larger number of objects around the vehicle 300 increase the risk rate. For example, the risk rate acquisition unit 511 calculates the risk rate such that a larger number of other vehicles around the vehicle 300 increase the risk rate. For example, the risk rate acquisition unit 511 calculates the risk rate such that a larger number of people around the vehicle 300 increase the risk rate. The risk rate acquisition unit 511 may determine the number, amount, and the like of objects around the vehicle 300 by using information acquired from the camera 311, the LiDAR 312, and the like.

For example, the risk rate acquisition unit 511 calculates the risk rate based on weather in an area where the vehicle 300 is located. The risk rate acquisition unit 511 calculates the risk rate such that the risk rate in so-called bad weather is higher than that in so-called good weather. In a specific example, the risk rate acquisition unit 511 calculates the risk rate such that the risk rate in rainy weather is higher than that in clear weather. The risk rate acquisition unit 511 may determine the weather in an area where the vehicle 300 is located based on information received from the server that provides weather information. The risk rate acquisition unit 511 may determine the weather in an area where the vehicle 300 is located by detecting a distant cloud from around the vehicle 300 or from the vehicle 300 with the camera 311.

The risk rate acquisition unit 511 may calculate the risk rate by another determination method.

Furthermore, the risk rate acquisition unit 511 may calculate the risk rate by combining a plurality of determination methods.

The cooling execution unit 508 may adjust the degree of cooling the SoCBox 400 in accordance with the risk rate acquired by the risk rate acquisition unit 511. For example, the cooling execution unit 508 preliminarily stores a first threshold and a second threshold higher than the first threshold for the risk rate. Then, when the risk rate is lower than a first threshold, the cooling execution unit 508 cools the SoCBox 400 with a first cooling intensity. When the risk rate is higher than the first threshold and lower than a second threshold, the cooling execution unit 508 cools the SoCBox 400 with a second cooling intensity higher than the first cooling intensity. When the risk rate is higher than the second threshold, the cooling execution unit 508 cools the SoCBox 400 with a third cooling intensity higher than the second cooling intensity. Note that the cooling intensity is not limited to having three stages.

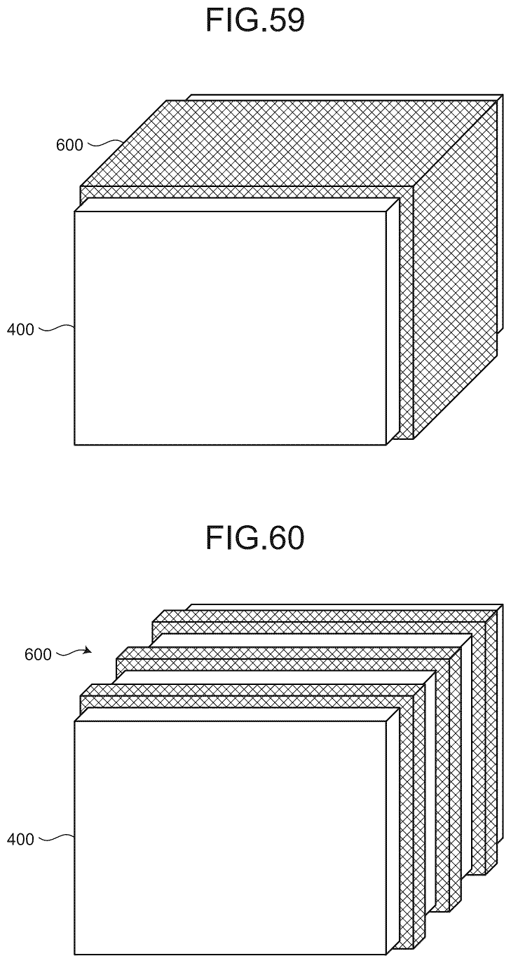

FIG. 59 schematically illustrates an example of the SoCBox 400 and the cooling unit 600. FIG. 59 illustrates a case where the cooling unit 600 includes one cooler. When predicting that the SoCBox 400 is starting heat generation or predicting that the SoCBox 400 has a temperature exceeding a predetermined threshold, the cooling execution device 500 starts cooling with the cooling unit 600. The cooling execution device 500 can thereby cool the entire SoCBox 400.

FIG. 60 schematically illustrates an example of the SoCBox 400 and the cooling unit 600. FIG. 60 illustrates a case where the cooling unit 600 includes a plurality of coolers each of which cools each of a plurality of portions of the SoCBox 400. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling.

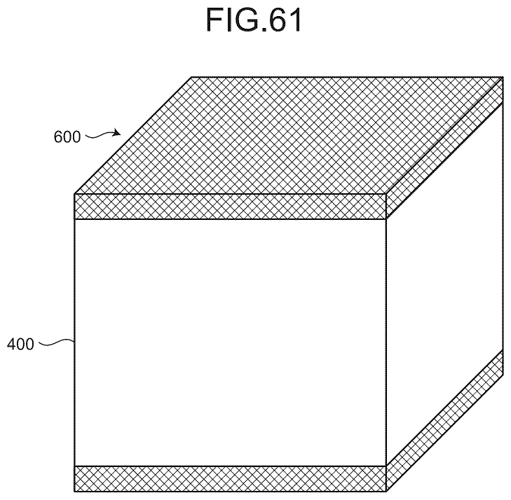

FIG. 61 schematically illustrates an example of the SoCBox 400 and the cooling unit 600. FIG. 61 illustrates a case where the cooling unit 600 includes two types of coolers. When predicting that one of a plurality of portions of the SoCBox 400 is starting heat generation or predicting that one of the plurality of portions has a temperature exceeding a predetermined threshold on the prediction of a temperature change of each of the plurality of portions, the cooling execution device 500 executes cooling using only a cooler suitable for the portion. The cooling execution device 500 can thereby perform efficient cooling. Furthermore, as the SoCBox 400 has an increasing temperature, the cooling execution device 500 increases the number of coolers to be used. That is, in the example, first, the cooling execution device 500 starts cooling using one of the two types of coolers. When the SoCBox 400 has a still increasing temperature, the cooling execution device 500 starts cooling using the other cooler. The cooling execution device 500 can thereby make energy to be used for cooling more efficient.

### Hardware Configuration Diagram

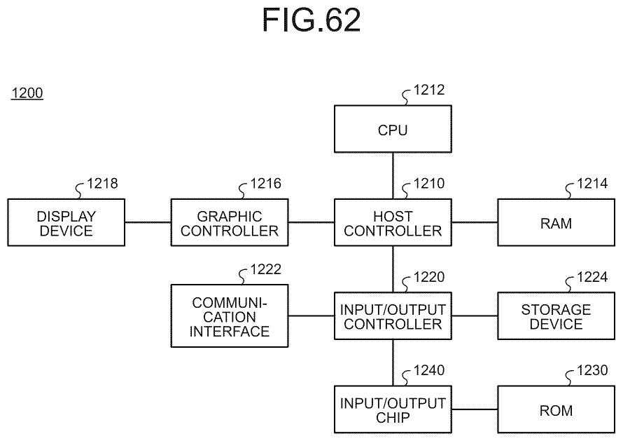

FIG. 62 schematically illustrates an example of a hardware configuration of a computer 1200 that functions as the management server 100, the SoCBox 400, the cooling execution device 500, or the cooling device 700. A program installed in the computer 1200 can cause the computer 1200 to function as one or a plurality of “units” of the device according to an embodiment, or can cause the computer 1200 to execute an operation related to the device according to the embodiment or the one or the plurality of “units”, and/or can cause the computer 1200 to execute a process according to the embodiment or a stage of the process. A CPU 1212 may execute such a program so that the computer 1200 executes a specific operation related to some or all of blocks in the flowcharts and block diagrams described in the present specification.

The computer 1200 according to the embodiment includes the CPU 1212, a RAM 1214, and a graphics controller 1216, which are mutually connected by a host controller 1210. The computer 1200 also includes input/output units such as a communication interface 1222, a storage device 1224, a DVD drive, and an IC card drive, which are connected to the host controller 1210 via an input/output controller 1220. The DVD drive may be a DVD-ROM drive, a DVD-RAM drive, or the like. The storage device 1224 may be a hard disk drive, a solid state drive, or the like. The computer 1200 also includes legacy input/output units such as a ROM 1230 and a keyboard, which are connected to the input/output controller 1220 via an input/output chip 1240.

The CPU 1212 operates in accordance with programs stored in the ROM 1230 and the RAM 1214 to control each of units. The graphics controller 1216 acquires image data generated by the CPU 1212 in a frame buffer or the like provided in the RAM 1214 or the RAM 1214 itself, and causes the image data to be displayed on a display device 1218.

The communication interface 1222 communicates with another electronic device via a network. The storage device 1224 stores a program and data to be used by the CPU 1212 in the computer 1200. The DVD drive reads a program or data from a DVD-ROM or the like, and provides the program or the data to the storage device 1224. The IC card drive reads a program and data from an IC card, and/or writes a program and data to the IC card.

The ROM 1230 internally stores a boot program and the like to be executed by the computer 1200 at the time of activation and/or a program depending on the hardware of the computer 1200. The input/output chip 1240 may also connect various input/output units to the input/output controller 1220 via a USB port, a parallel port, a serial port, a keyboard port, a mouse port, or the like.

The program is provided by a computer-readable storage medium such as a DVD-ROM and an IC card. The program is read from the computer-readable storage medium, installed in the storage device 1224, the RAM 1214, or the ROM 1230, which is also an example of the computer-readable storage medium, and executed by the CPU 1212. Information processing written in the program is read by the computer 1200, and provides cooperation between the program and the above-described various types of hardware resources. A device or a method may be configured by performing an operation or processing of information in accordance with the use of the computer 1200.

For example, when communication is executed between the computer 1200 and an external device, the CPU 1212 may execute a communication program loaded in the RAM 1214, and instruct the communication interface 1222 to perform communication processing based on processing written in the communication program. Under the control of the CPU 1212, the communication interface 1222 reads transmission data stored in a transmission buffer region provided in a recording medium such as the RAM 1214, the storage device 1224, the DVD-ROM, and the IC card, transmits the read transmission data to the network, or writes reception data received from the network to a reception buffer region or the like provided on the recording medium.

Furthermore, the CPU 1212 may cause the RAM 1214 to read all or a necessary part of a file or a database stored in an external recording medium such as the storage device 1224, the DVD drive (DVD-ROM), and the IC card, and may execute various types of processing on data on the RAM 1214. Next, the CPU 1212 may write back the processed data to the external recording medium.

Various types of information such as various types of programs, data, tables, and databases may be stored in a recording medium, and subjected to information processing. The CPU 1212 may execute various types of processing on the data read from the RAM 1214. The various types of processing include various types of operations, information processing, conditional determination, conditional branching, unconditional branching, and information search/replacement, which are described throughout the present disclosure and specified by an instruction sequence of a program. The CPU 1212 writes back the result to the RAM 1214. Furthermore, the CPU 1212 may search for information in a file, a database, and the like in the recording medium. For example, when the recording medium stores a plurality of entries each having an attribute value of a first attribute associated with an attribute value of a second attribute, the CPU 1212 may search for an entry in which the attribute value of the first attribute matches a specified condition from the plurality of entries, read the attribute value of the second attribute stored in the entry, and thereby acquire the attribute value of the second attribute associated with the first attribute that satisfies a predetermined condition.

A computer-readable storage medium on the computer 1200 or near the computer 1200 may store the above-described program or a software module. Furthermore, a recording medium such as a hard disk and a RAM provided in a server system connected to a dedicated communication network or the Internet can be used as a computer-readable storage medium. This causes a program to be provided to the computer 1200 via the network.

Blocks in the flowcharts and block diagrams in the embodiment may represent stages of a process in which an operation is performed or “units” of a device having a role of executing the operation. Specific stages and “units” may be implemented by a dedicated circuit, a programmable circuit, and/or a processor. The programmable circuit is supplied with a computer-readable instruction stored on the computer-readable storage medium. The processor is supplied with a computer-readable instruction stored on the computer-readable storage medium. The dedicated circuit may include a digital and/or analog hardware circuit, and may include an integrated circuit (IC) and/or a discrete circuit. The programmable circuit may include a reconfigurable hardware circuit including, for example, AND, OR, exclusive OR, NAND, NOR, and other logical operations, a flip-flop, a register, and a memory element, such as a field programmable gate array (FPGA) and a programmable logic array (PLA).

The computer-readable storage medium may include any tangible device capable of storing an instruction to be executed by an appropriate device. As a result, the computer-readable storage medium storing the instruction includes a product including an instruction that can be executed to create a means for executing an operation specified by a flowchart or a block diagram. Examples of the computer-readable storage medium may include an electronic storage medium, a magnetic storage medium, an optical storage medium, an electromagnetic storage medium, and a semiconductor storage medium. More specific examples of the computer-readable storage medium may include a floppy (registered trademark) disk, a diskette, a hard disk, a random-access memory (RAM), a read-only memory (ROM), an erasable programmable read-only memory (EPROM or flash memory), an electrically erasable programmable read-only memory (EEPROM), a static random-access memory (SRAM), a compact disk read-only memory (CD-ROM), a digital versatile disk (DVD), a Blu-ray (registered trademark) disk, a memory stick, and an integrated circuit card.

The computer-readable instruction may include an assembler instruction, an instruction set architecture (ISA) instruction, a machine instruction, a machine-dependent instruction, a microcode, a firmware instruction, state setting data, or one of a source code and an object code written in any combination of one or a plurality of programming languages. The one or the plurality of programming languages include object-oriented programming languages, such as Smalltalk (registered trademark), JAVA (registered trademark), and C++, and conventional procedural programming languages, such as a “C” programming language and a similar programming language.

The computer readable instruction may be provided to a general purpose computer, a special purpose computer, or a processor of another programmable data processing device, or a programmable circuit locally or via a local area network (LAN) or via a wide area network (WAN) such as the Internet so that the general purpose computer, the special purpose computer, or the processor of the other programmable data processing device, or the programmable circuit execute the computer-readable instruction to generate the means for executing an operation specified in a flowchart or a block diagram. Examples of the processor include a computer processor, a processing unit, a microprocessor, a digital signal processor, a controller, and a microcontroller.

Although the present invention has been described by using the embodiments, the technical scope of the present invention is not limited to the scope described in the above-described embodiments. It is clear to those skilled in the art that various modifications or improvements can be made to the above-described embodiments. It is clear from the claims that modes to which such modifications or improvements are added can also be included in the technical scope of the present invention.

It should be noted that the order of execution of pieces of processing, such as operations, procedures, steps, and stages, in a device, a system, a program, and a method illustrated in the claims, the specification, and the drawings is not particularly clarified by “before”, “prior to”, and the like and the pieces of processing can be performed in any order unless output in the previous processing is used in the subsequent processing. Even if an operation flow in the claims, the specification, and the drawings has been described by using “first”, “next”, and the like for convenience, the description does not mean that performing the operation flow in this order is essential.

Although the present invention has been described by using the embodiments, the technical scope of the present invention is not limited to the scope described in the above-described embodiments. It is clear to those skilled in the art that various modifications or improvements can be made to the above-described embodiments. It is clear from the claims that modes to which such modifications or improvements are added can also be included in the technical scope of the present invention.

It should be noted that the order of execution of pieces of processing, such as operations, procedures, steps, and stages, in a device, a system, a program, and a method illustrated in the claims, the specification, and the drawings is not particularly clarified by “before”, “prior to”, and the like and the pieces of processing can be performed in any order unless output in the previous processing is used in the subsequent processing. Even if an operation flow in the claims, the specification, and the drawings has been described by using “first”, “next”, and the like for convenience, the description does not mean that performing the operation flow in this order is essential.

### REFERENCE SIGNS LIST

10 SYSTEM
20 NETWORK
30 SERVER
40 TEMPERATURE SENSOR
100 MANAGEMENT SERVER
102 INFORMATION ACQUISITION UNIT
104 MODEL GENERATION UNIT
106 MODEL PROVIDING UNIT
108, 507 CREATION UNIT
110, 506 PREDICTION UNIT
200, 200-1 to 200-4, 300 VEHICLE
210, 310 SENSOR
212, 312 LiDAR
213, 313 MILLIMETER-WAVE SENSOR
214, 314 ULTRASONIC SENSOR
215, 315 IMU SENSOR
216, 316 GNSS SENSOR
217, 317 GPS SENSOR
400 SoCBox
500 COOLING EXECUTION DEVICE
501 DETECTION UNIT
502, 550 MODEL STORAGE UNIT
504, 560 INFORMATION ACQUISITION UNIT
505 ESTIMATION UNIT
508 COOLING EXECUTION UNIT
509 OUTPUT UNIT
510 SELECTION UNIT
511 RISK RATE ACQUISITION UNIT
520 COMMUNICATION UNIT
530 INSTRUCTION UNIT
540 COOLING EXECUTION UNIT
600 COOLING UNIT
700 COOLING DEVICE
1200 COMPUTER
1210 HOST CONTROLLER
1212 CPU
1214 RAM
1216 GRAPHIC CONTROLLER
1218 DISPLAY DEVICE
1220 INPUT/OUTPUT CONTROLLER
1222 COMMUNICATION INTERFACE
1224 STORAGE DEVICE
1230 ROM
1240 INPUT/OUTPUT CHIP

1-79. (canceled)

80. A cooling device comprising:
a processor configured to:
predicts a temperature change of a control device that controls automatic driving of a vehicle and that is mounted on the vehicle;
communicates with another vehicle within a predetermined range based on the temperature change predicted; and
instructs the control device to execute arithmetic related to control of automatic driving of the other vehicle.

81. The cooling device according to claim 80,
wherein
the processor determines another vehicle within a range in which communication with the other vehicle is allowed to be maintained for a predetermined time as a vehicle within the predetermined range, and communicate with the vehicle.

82. The cooling device according to claim 80,
wherein
the processor is further configured to
starts cooling the control device based on the temperature change predicted.

83. The cooling device according to claim 82,
wherein, when the processor predicts that a temperature of the control device becomes higher than a predetermined threshold, the processor starts cooling the control device.

84. The cooling device according to claim 80,
wherein
the processor predicts the temperature change of the control device by AI.

85. The cooling device according to claim 84,
wherein
the processor is further configured to
stores a learning model in which information acquired by the control device is used as input and a temperature change of the control device is used as output, the learning model being generated by machine learning using, as learning data, the information acquired by the control device and the temperature change of the control device at a time when the control device acquires the information; and
acquires the information acquired by the control device,
wherein
the processor predicts the temperature change of the control device by inputting the information acquired to the learning model.

86. The cooling device according to claim 85,
wherein
the processor acquires sensor information acquired by the control device from a sensor mounted on the vehicle from the sensor or the control device.

87. The cooling device according to claim 85,
wherein
the processor acquires, from the control device, an analysis result obtained by the control device analyzing a captured image captured by a camera mounted on the vehicle.

88. The cooling device according to claim 85,
wherein
the processor acquires external information received by the control device from an external device from the external device or the control device.

89. The cooling device according to claim 88,
wherein
the processor acquires traffic information on a road where the vehicle is located, received by the control device from the external device from the external device or the control device.

90. The cooling device according to claim 82,
wherein
the processor starts cooling the control device by using one or a plurality of coolers selected from a plurality of types of coolers in accordance with a level of a temperature of the control device predicted.

91. The cooling device according to claim 90,
wherein the plurality of types of coolers includes a plurality of one or a plurality of types of air coolers, one or a plurality of types of water coolers, and a liquid nitrogen cooler.

92. The cooling device according to claim 91,
wherein
the processor predicts a temperature change of each of a plurality of portions of the control device, and
the processor starts cooling the control device by using a cooler selected from a plurality of coolers each of which cools each of the plurality of portions of the control device based on a prediction result.

93. The cooling device according to claim 92,
wherein the control device includes a plurality of processing chips arranged at different positions of the control device, and
each of the plurality of coolers is arranged at a position of each of the plurality of processing chips.

94. A cooling method to be executed by a cooling device, comprising:
predicting a temperature change of a control device that controls automatic driving of a vehicle and that is mounted on the vehicle;
communicating with another vehicle within a predetermined range based on the temperature change predicted by the predicting and
instructing the control device to execute arithmetic related to control of automatic driving of the other vehicle with which communication is performed by the communicating.

95. A non-transitory computer-readable recording medium having stored therein a cooling program causing a computer to execute:
predicting a temperature change of a control device that controls automatic driving of a vehicle and that is mounted on the vehicle;
communicating with another vehicle within a predetermined range based on the temperature change predicted in the prediction procedure; and
instructing the control device to execute arithmetic related to control of automatic driving of the other vehicle with which communication is performed in the communication procedure.

96-107. (canceled)
